(19) United States
(12) Patent Application Publication
(10) Pub. No.: US 2026/0322338 A1
(43) Pub. Date: Oct. 15, 2026

(54) AMPLIFIER CURRENT CLAMPING VIA INTERNAL AMPLIFIER CONTROL NODES

(71) Applicant: Analog Devices, Inc., Wilmington, MA (US)

(72) Inventor: Alec Julius Poitzsch, Woburn, MA (US)

(21) Appl. No.: 19/637,156

(22) Filed: Apr. 2, 2026

Related U.S. Application Data
(60) Provisional application No. 63/785,945, filed on Apr. 9, 2025.

(51) Int. Cl. H03F 1/56; H03F 3/45

(52) U.S. Cl. CPC H03F 1/56; H03F 3/45475; H03F 2200/387; H03F 2200/426

(57) ABSTRACT

An apparatus includes a clamping circuit configured to electronically couple to an amplifier. The clamping circuit includes a measurement stage and an output stage. The measurement stage is configured to, responsive to a determination that an output current of the amplifier circuit is below a threshold, control the output stage to maintain a first impedance influence at one or more internal control nodes of the amplifier, where the first impedance influence does not substantially alter a performance shaping operation applied to an output drive of the amplifier. The measurement stage is further configured to, responsive to a determination that the output current of the amplifier circuit is above a threshold, control the output stage to apply a second impedance influence at the internal control node of the amplifier, where the second impedance influence applies a current clamping function at the output drive of the amplifier without shutting the amplifier down.

### BACKGROUND

Embodiments described herein relate to amplifiers, and more particularly, to novel techniques for applying current clamping to amplifiers. In one or more embodiments, the novel techniques leverage an internal control node of the amplifier and applies a controlled bias signal (e.g., a direct current (DC) bias) to the internal control node only when an overcurrent condition is present. In one or more embodiments, the internal control node is configured to also govern large signal drive strength. In one or more embodiments, the internal control node is accessed through one or more external compensation pins.

A voltage output amplifier delivers output current determined by the impedance characteristics of a load. If the load impedance is low due to a short-circuit fault event, the amplifier can attempt to deliver an excessive amount of output current, which can be destructive to the load, to the amplifier, and potentially to the power supply. A clamping approach can be used to constrain the output current to remain at or below a selected limit when the load condition would otherwise cause the current to rise beyond a safe level. When the limit is reached, the amplifier's output behavior is influenced so that additional demand from the load does not result in additional output current. It is desirable to provide amplifier current clamping techniques that are efficient and effective.

### SUMMARY

Various embodiments of systems, apparatuses, and methods for implementing clamping circuits for amplifiers are contemplated.

In one or more embodiments, an apparatus is implemented that includes a clamping circuit configured to electronically couple to an amplifier circuit. The clamping circuit includes a measurement stage and an output stage. The measurement stage is configured to, responsive to a determination that an output current of the amplifier circuit is below a threshold, control the output stage to maintain a first impedance influence at one or more internal control nodes of the amplifier circuit, where the first impedance influence does not substantially alter a performance shaping operation applied to an output drive of the amplifier circuit. The measurement stage is further configured to, responsive to a determination that the output current of the amplifier circuit is above a threshold, control the output stage to apply a second impedance influence at the one or more internal control nodes of the amplifier circuit, where the second impedance influence applies a current clamping function at the output drive of the amplifier circuit.

In one or more embodiments, a clamping circuit is implemented from I_{OUT} to COMP pin(s) of an amplifier. In this embodiment, the input to the clamping circuit is one or more measurements of the output current (I_{OUT}) of the amplifier, either directly or indirectly via supply current. The output of the clamping circuit is coupled to one or more external compensation pins (COMP) of the amplifier, wherein the one or more external compensation pins correspond to internal high impedance nodes of the amplifier. If the measured current is at or below the current clamp threshold, the clamping circuit output is high impedance at COMP. If the measured current is above the current clamp threshold I_{LIMIT}, the clamping circuit output is low impedance at COMP to a DC voltage which impedes the amplifier ability to deliver output current. In this state, the clamping circuit has an output impedance which decreases as the output current measurement in excess of the limit (I_{OUT}−I_{LIMIT}).

These and other embodiments will become apparent upon consideration of the following description and accompanying drawings.

### BRIEF DESCRIPTION OF THE DRAWINGS

FIG. 1 is a simplified block diagram illustrating a system in accordance with one or more embodiments;

FIG. 2 is a flow diagram illustrating a method in accordance with one or more embodiments;

FIG. 3 is a diagram illustrating a circuit that conveys the concept, leveraged by one or more embodiments of the disclosure, that an amplifier's output current depends on the load impedance connected to the output;

FIG. 4 is a diagram illustrating a circuit that conveys the concept, leveraged by one or more embodiments of the disclosure, that when the load is capacitive, the output current influences how fast the output voltage can change;

FIG. 5 is a diagram illustrating an amplifier with a single external compensation pin in accordance with one or more embodiments;

FIG. 6 is a diagram illustrating an amplifier with complementary external compensation pins in accordance with one or more embodiments;

FIG. 7 is a diagram illustrating an amplifier with external current clamping via external compensation pins in accordance with one or more embodiments;

FIG. 8 is a diagram illustrating an amplifier with a current clamp high impedance output in accordance with one or mor embodiments;

FIG. 9 is a diagram illustrating an amplifier with a current clamp high impedance output in accordance with one or more embodiments;

FIG. 10 is a diagram illustrating unipolar current clamping via a single external compensation pin in accordance with one or more embodiments;

FIG. 11 is a diagram illustrating a unipolar current clamp low impedance output when output current exceeds a threshold in accordance with one or more embodiments;

FIG. 12 is a diagram illustrating an amplifier with complementary current clamping via complementary external compensation pins in accordance with one or more embodiments;

FIG. 13 is a diagram illustrating an amplifier with complementary current clamp low impedance outputs in accordance with one or more embodiments;

FIG. 14 is a diagram illustrating an amplifier with single transistor complementary current clamping via complementary external compensation pins with supply-side shunt resistors in accordance with one or more embodiments;

FIG. 15 is a diagram illustrating an amplifier with single transistor complementary current clamping via external compensation with an output shunt resistor in accordance with one or more embodiments;

FIG. 16 is a diagram illustrating an amplifier employing transistor pair complementary current clamping via complementary external compensation pins with supply-side shunt resistors in accordance with one or more embodiments;

FIG. 17 is a diagram illustrating an amplifier employing transistor pair complementary current clamping via external compensation with an output shunt resistor in accordance with one or more embodiments;

FIG. 18 is a diagram illustrating an amplifier employing comparator and transistor complementary current clamping via complementary external compensation pins with supply-side shunt resistors in accordance with one or more embodiments;

FIG. 19 is a diagram illustrating an amplifier employing comparator and transistor complementary current clamping via external compensation with an output shunt resistor in accordance with one or more embodiments;

FIG. 20 is a generalized flow diagram illustrating a method for employing current clamping via external compensation in accordance with one or more embodiments;

FIG. 21 is a generalized flow diagram illustrating a method for employing software control of current clamping via external compensation in accordance with one or more embodiments; and

FIG. 22 is a simplified block diagram illustrating a computer system in accordance with one or more embodiments.

While the methods and mechanisms described herein are susceptible to various modifications and alternative forms, specific embodiments are shown by way of example in the drawings and are herein described in detail. It should be understood, however, that drawings and detailed description thereto are not intended to limit the methods and mechanisms to the particular form disclosed, but on the contrary, are intended to cover all modifications, equivalents and alternatives apparent to those skilled in the art once the disclosure is fully appreciated.

### DETAILED DESCRIPTION

Amplifiers can be used to drive electrical signals into loads such as sensors, actuators, or test fixtures. The amount of output current depends on the load impedance. Under fault conditions like a short circuit, a load can attempt to draw more than the amplifier's maximum rated current, which can damage the load, the amplifier, or the power supply and can interrupt testing or system operation.

Embodiments of the disclosure address the damage that can result from an amplifier attempting to output more than its maximum rated or designed current by providing novel amplifier current clamping techniques that are efficient, effective and leverage existing amplifier functionality. The disclosed clamping techniques provide a flexible protection schemes for systems that need to drive through predictable fault events or that require precise control over the maximum current draw and the associated slew rate into capacitive loads. Embodiments of the disclosure provide the flexibility to set and adjust current limits externally, with fast response and stable behavior across a range of operating scenarios.

In one or more embodiments, the disclosed clamping technique leverages one or more internal amplifier control nodes that couple downstream to an amplifier output drive that generates the amplifier output. The one or more internal amplifier control nodes couple upstream to amplifier circuitry configured to perform amplifier output controls that are part of the core amplification operations of the amplifier design. The disclosed clamping technique configures at least one of these internal amplifier nodes to perform dual-role functionality, which means that, in addition to its as-designed amplification functionality, the at least one of these internal amplifier nodes is also configured to perform clamping techniques under control of an external and configurable clamping circuit. In one or more embodiments, the clamping circuit monitors the amplifier's output current, either directly with an output shunt resistor or indirectly by measuring supply current with a shunt resistor. The measured current is compared against a threshold. When the measured current is at or below the threshold, the clamping circuit presents a high impedance to the internal amplifier control node. In one or more embodiments, the clamping circuit accesses the internal amplifier control node through a control node interface of the amplifier, When the measured current exceeds the threshold, the clamping circuit presents a low impedance to a DC voltage at the control node interface, which reduces the drive capability of the amplifier output drive and limits current. This approach forms a compact, fast control loop that acts directly at a high impedance control node of the amplifier, thereby enabling stable current limiting without shutting the amplifier down

In one or more embodiments, the control node interface is one or more external pins commonly referred to as compensation pins, and the internal control node is one or more internal high impedance nodes used to stabilize the amplifier's output frequency response. These pins are employed to tailor the amplifier's output frequency response, but they also provide a direct, high sensitivity interface to the amplifier's internal control nodes. In one or more embodiments, the clamping circuit monitors the amplifier's output current, either directly with an output shunt resistor or indirectly by measuring supply current with a shunt resistor. The measured current is compared against a threshold. When the measured current is at or below the threshold, the clamping circuit presents a high impedance to the compensation pin, leaving the amplifier's output drive unaffected. When the measured current exceeds the threshold, the clamping circuit presents a low impedance to a DC voltage at the compensation pin, which reduces the drive capability of the output stage and limits current. This approach forms a compact, fast control loop that acts directly at the amplifier's high impedance node, enabling stable current limiting without shutting the amplifier down.

The disclosed clamping technique is compatible with single-pin and complementary-pin compensation architectures. With a single compensation pin, the circuit can clamp current in one direction, for example limiting sourcing current when the output attempts to drive high into a fault. With complementary compensation pins, separate measurements of sourcing and sinking currents can be applied to each pin, allowing independent control of both directions. In an example scenario, if a capacitive load requires a lower maximum source current to achieve a desired slew rate, the clamping circuit can pull the high-side compensation pin toward the positive supply when the measured source current exceeds the threshold, thereby reducing the effective transconductance of the output device and holding the current near the limit. Similarly, if a resistive short to ground increases sinking current beyond a set level, the disclosed clamping circuit can pull the low-side compensation pin toward the negative supply to limit current in the opposite direction

Multiple circuit implementations may be used to realize the clamping behavior of the disclosed clamping circuit. In an no-limiting example, a simple configuration employs a single transistor driven by the voltage across a shunt resistor, producing a high or low impedance at the compensation pin depending on whether the measured current is below or above the threshold. A transistor pair configuration increases gain and input impedance for stronger control at the compensation node. A comparator-driven transistor implementation provides high accuracy and allows programmable thresholds set by an input voltage, which can be generated by software-controlled circuitry. In supply-shunt configurations, the measurement path is simple and uses low voltage components. In output-shunt configurations, the measurement reflects only the amplifier's output current and can be level shifted to the supply rails for precise control. These implementations enable users to select the accuracy, complexity, and programmability appropriate for their system.

By acting directly at one or more of the amplifier's control node interfaces in response to measured output current, embodiments of the disclosure allow the amplifier to continue operating while maintaining output current near a chosen limit. This helps prevent damage during fault events, avoids disruptive shutdowns, and gives users practical control over output behavior such as slew rate into capacitive loads. For example, in a test system driving a capacitive probe, the clamping circuit can hold the current at a set level so that the output voltage rises at a controlled rate, improving stability and repeatability without redesigning the amplifier itself. In production environments where transient shorts occur, the amplifier can keep delivering a controlled current rather than shutting down, preserving test flow and protecting equipment.

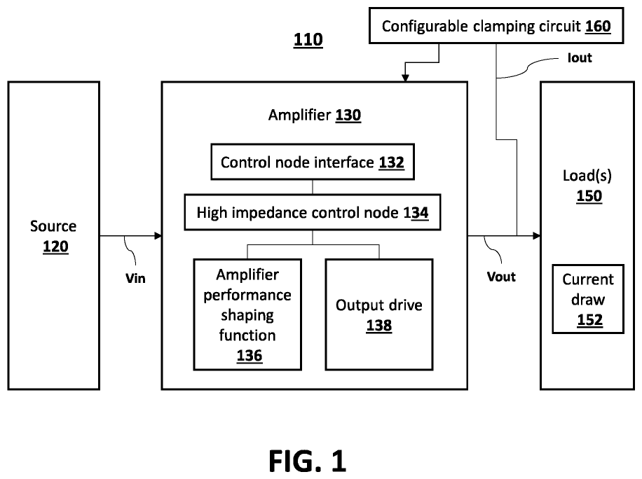

Turning now to a more detailed description of embodiments of the disclosure, FIG. 1 depicts components of a system 110 configured to incorporate a configurable clamping circuit 160 embodying aspects of the disclosure. The system 110 can be any system that incorporates signal amplification functionality, which is provided in the system 110 by an amplifier circuit 130. The system 110 includes a source 120, the amplifier circuit 130, and one or more load(s) 150. The amplifier circuit 130 includes a control node interface 132 and one or more instances of a high impedance control node 134. The high impedance control node 134 is coupled upstream to circuitry configured to execute amplifier performance shaping function(s) 136, and is further coupled downstream to an output drive of the amplifier circuit 130. In accordance with disclosed embodiments, the configurable clamping circuit 160 is configured to, in effect, reconfigure the high impedance control node 134 such that, in addition to controlling frequency response/domain behavior, the high impedance control node 134 also provides clamping functionality through the output drive 138.

In one or more embodiments, the system 110 can be implemented as a test and measurement system that applies controlled voltages to a device under test while monitoring response signals. For example, the source 120 can provide an input signal Vin corresponding to a programmed stimulus, the amplifier circuit 130 can generate an amplified output signal Vout, and the load 150 can include a cable harness, a test fixture, a probe card, a socketed device under test, or a combination thereof. In such environments, wiring faults, misconnections, or device failures can present a low impedance condition at the output that would otherwise cause excessive output current. The configurable clamping circuit 160 can limit output current while allowing continued operation of the system 110 so that a test sequence can proceed, pause, or recover without requiring a full shutdown of the amplifier circuit 130.

In one or more embodiments, the system 110 can be implemented as an industrial or laboratory control system that drives an actuator, transducer, or other electromechanical element. By way of example, the load 150 can include a piezoelectric actuator, a capacitive transducer, a motor driver input stage, or a positioning element. In these cases, the load 150 may exhibit time varying impedance and may include substantial capacitance such that the output current drawn by the load 150 depends on the rate of change of Vout. The configurable clamping circuit 160 can be used to constrain the output current drawn by the load 150 during large signal transitions, thereby reducing stress on the output drive 138 and improving controllability of the driven element.

In one or more embodiments, the system 110 can be implemented as a communications, sensor excitation, or data acquisition system in which the amplifier circuit 130 drives a signal into a sensor, a remote line, or a conditioning network that is subject to unexpected loading. For example, the load 150 can include one or more sensors, resistive networks, capacitive elements, protection circuits, or connectors exposed to external environments. The configurable clamping circuit 160 can provide protection against intermittent short circuits and other fault conditions while maintaining a defined operating mode of the amplifier circuit 130.

In one or more embodiments, the source 120 can be implemented using one or more of a digital to analog converter, a programmable waveform generator, a controller with an output interface, or a feedback network that generates Vin based on one or more sensed parameters. The amplifier circuit 130 can be implemented as an operational amplifier, a power amplifier, a high voltage amplifier, or another analog amplifier topology that includes the control node interface 132 coupled to the high impedance control node 134. The configurable clamping circuit 160 can be implemented using analog circuitry mounted on a printed circuit board and coupled to the amplifier circuit 130 within the system 110. The load 150 can be implemented as any element or collection of elements that pull a current draw 152 from the output drive 138 during operation of the system 110.

In one or more embodiments, the amplifier circuit 130 is configured to perform signal amplification by receiving an input signal Vᵢₙ and generating an output signal Vₒᵤₜ that is based on the input signal and a selected transfer characteristic of the amplifier circuit 130. For example, the amplifier circuit 130 can be configured to provide voltage gain, buffering, impedance translation, level shifting, filtering, and or driving capability for the load 150. In certain configurations, the amplifier circuit 130 can be arranged to maintain Vₒᵤₜ at a value that tracks Vᵢₙ according to a closed loop relationship that is established by one or more external components coupled to the amplifier circuit 130

In one or more embodiments, the amplifier circuit 130 includes an input stage configured to receive one or more input signals, an intermediate stage configured to provide gain, and an output stage configured to source and or sink output current to drive the load 150. The amplifier circuit 130 can be powered by one or more supply rails and can be configured for single supply or dual supply operation. The amplifier circuit 130 can be implemented as a monolithic integrated circuit, as a multi die module, or as a circuit implemented using discrete components. In some embodiments, the amplifier circuit 130 is implemented as an operational amplifier that is configured, using one or more external feedback components, to operate as a voltage follower, an inverting amplifier, a noninverting amplifier, an integrator, a differentiator, a transimpedance amplifier, a summing amplifier, or another analog computation block.

In one or more embodiments, the amplifier circuit 130 is configured to drive a variety of load types including resistive loads, capacitive loads, inductive loads, and combinations thereof. For example, when the load 150 includes capacitance, the output current provided by the amplifier circuit 130 can be associated with a rate of change of the output voltage according to I=C(dVout/dt). When the load 150 includes resistance, the output current can be associated with an output voltage and the resistance value according to I=Vout/R. In operation, the amplifier circuit 130 can respond to changes in Vin, changes in the load 150, and transient events at the output by adjusting the output stage drive to maintain the selected transfer characteristic while remaining within operating limits of the amplifier circuit 130

In one or more embodiments, the amplifier circuit 130 can include one or more auxiliary pins or terminals that support configuration, monitoring, and control functions. By way of example, such pins or terminals can support one or more of enable and disable control, shutdown control, offset adjustment, gain selection, diagnostic reporting, and other functions that facilitate integration of the amplifier circuit 130 into the system 110. The amplifier circuit 130 can further be configured to operate in conjunction with protection circuitry, such as thermal protection, undervoltage detection, and other circuits that reduce the likelihood of damage under abnormal operating conditions.

In addition to the features and functions described above, in accordance with one or more embodiments, the amplifier circuit 130 includes the control node interface 132, the high impedance control node 134, circuitry configured to execute the amplifier performance shaping function(s) 136, and the output drive 138. In one or more embodiments, the control node interface 132 is a coupling structure that provides access, at least in part, to one or more internal control nodes of the amplifier circuit 130. The control node interface 132 can be configured to couple signals, impedances, and or bias conditions between circuitry external to the amplifier circuit 130 and circuitry internal to the amplifier circuit 130. The control node interface 132 can be implemented as one or more pins, pads, terminals, leads, lands, or other package interfaces of an integrated circuit device. In one or more embodiments, the control node interface 132 can be implemented as a conductive trace, bond wire, connector, or interconnect within a module or printed circuit board assembly. In one or more embodiments, the control node interface 132 can be implemented as a switching network, a programmable interconnect, or a selectable routing arrangement that couples one or more of multiple internal nodes to an external interface.

In one or more embodiments, the high impedance control node 134 is an internal node of the amplifier circuit 130 that is characterized by a relatively high impedance when compared to an output node of the amplifier circuit 130. The high impedance control node 134 can be located within one or more gain stages of the amplifier circuit 130 and can be coupled to an internal node that influences operation of downstream circuitry including the output drive 138. The high impedance control node 134 can be implemented as a transistor gate node, a transistor base node, a cascode control node, a current mirror control node, a node coupled to one or more bias generators, or another internal node at which relatively small currents can influence amplifier behavior. In one or more embodiments, the amplifier circuit 130 includes a single high impedance control node 134. In some embodiments, the amplifier circuit 130 includes multiple instances of the high impedance control node 134 that are associated with different internal paths, different gain stages, and or different directions through the output drive 138.

In one or more embodiments, the circuitry configured to execute the amplifier performance shaping function(s) 136 includes circuitry that shapes one or more operating characteristics of the amplifier circuit 130. The circuitry configured to execute the amplifier performance shaping function(s) 136 can implement, for example, frequency response shaping, transient response shaping, stability control, slew behavior control, or other response conditioning behavior of the amplifier circuit 130. The circuitry configured to execute the amplifier performance shaping function(s) 136 can include one or more capacitors, resistors, transconductance elements, current sources, current mirrors, and or active devices arranged to establish or adjust loop dynamics of the amplifier circuit 130. In one or more some embodiments, the circuitry configured to execute the amplifier performance shaping function(s) 136 is implemented fully within an integrated circuit die. In other embodiments, at least a portion of the circuitry configured to execute the amplifier performance shaping function(s) 136 is implemented using one or more external components coupled through the control node interface 132 such that an external impedance or network contributes to the amplifier performance shaping function(s) 136.

In one or more embodiments, the output drive 138 includes circuitry configured to generate an output signal and to source and or sink output current to drive the load 150. The output drive 138 can be implemented as a push pull output stage, a class AB stage, a class A stage, a class D stage, a source follower stage, an emitter follower stage, or another output topology suitable for providing load current. In one or more embodiments, the output drive 138 includes complementary transistor devices configured to source current from a positive supply rail and sink current to a negative supply rail. In one or more embodiments, the output drive 138 is implemented as a single ended output stage referenced to a supply rail. The output drive 138 can be implemented using bipolar transistors, field effect transistors, laterally diffused MOS devices, gallium nitride devices, silicon carbide devices, or combinations thereof depending on a target voltage, current, and power capability. In some embodiments, the output drive 138 includes one or more protection elements such as current limiting devices, thermal sensing elements, safe operating area protection, and or shutdown control circuitry. In operation, the output drive 138 can be controlled by upstream gain stages of the amplifier circuit 130 to adjust an output voltage in accordance with the input signal Vin and a selected closed loop relationship, while providing output current demanded by the load 150 within operating limits of the amplifier circuit 130.

In one or more embodiments, the configurable clamping circuit 160 is circuitry configured to interact with the amplifier circuit 130 to limit an output current delivered by the output drive 138 under one or more conditions. The configurable clamping circuit 160 can be coupled to the amplifier circuit 130 through the control node interface 132 such that the configurable clamping circuit 160 can influence the high impedance control node 134. In operation, the configurable clamping circuit 160 can monitor or otherwise derive information indicative of output current demand, and can selectively alter an effective impedance condition presented to the control node interface 132. By selectively changing the effective impedance condition, the configurable clamping circuit 160 can cause a corresponding change at the high impedance control node 134 that affects operation of circuitry within the amplifier circuit 130.

In one or more embodiments, the high impedance control node 134 is coupled to the circuitry configured to execute the amplifier performance shaping function(s) 136 and is further coupled to the output drive 138. Accordingly, changes at the high impedance control node 134 can influence operation of the amplifier performance shaping function(s) 136 and can also influence a drive capability of the output drive 138. The configurable clamping circuit 160 can be configured so that, when a measured current Iin is below a threshold, the configurable clamping circuit 160 presents a relatively high impedance to the control node interface 132 such that the high impedance control node 134 continues to support the amplifier performance shaping function(s) 136.

When the measured current Iin satisfies a clamp condition, the configurable clamping circuit 160 can present a relatively low impedance to a reference potential at the control node interface 132 such that the high impedance control node 134 is driven toward a corresponding reference level. Because the high impedance control node 134 is a sensitive internal control point, coupling the node to the reference potential through the relatively low impedance establishes a defined bias condition at the high impedance control node 134 and reduces the effect of other influences that would otherwise cause the node voltage to move in a direction that increases output drive. In one or more embodiments, this defined bias condition reduces a drive signal applied to one or more transistors of the output drive 138 or reduces a bias current associated with the output drive 138, thereby reducing an effective transconductance of the output drive 138. As a result, when the load 150 attempts to draw additional current, the output drive 138 is prevented from further increasing conduction and the output current is constrained to substantially hold at a clamp level.

In one or more embodiments, the relatively low impedance coupling acts as a clamp that holds the high impedance control node 134 near the reference level while the clamp condition persists. This causes the amplifier circuit 130 to trade off voltage regulation for current regulation during the clamp condition such that increases in load demand primarily produce a change in Vout rather than a continued increase in output current. When the measured current Iin no longer satisfies the clamp condition, the configurable clamping circuit 160 returns to presenting the relatively high impedance to the control node interface 132 so that the high impedance control node 134 again operates primarily in support of the amplifier performance shaping function(s) 136. In this manner, the amplifier circuit 130 can continue operating while output current is constrained.

In one or more embodiments, the configurable clamping circuit 160 includes a sense portion configured to generate a sense signal indicative of a current associated with operation of the amplifier circuit 130. The sense portion can be implemented using a shunt resistor positioned to sense a supply current of the amplifier circuit 130 or an output current delivered to the load 150, and the sense portion can include filtering elements that reduce sensitivity to switching noise or transient spikes. In other embodiments, the sense portion is implemented using a current mirror, a sense transistor, a hall effect sensor, or another current sensing structure that produces a voltage or current proportional to the measured current. In some embodiments, the sense portion is arranged to sense sourcing current and sinking current separately using separate sense elements associated with respective supply paths or output paths.

In one or more embodiments, the configurable clamping circuit 160 includes a control portion configured to compare the sense signal to a reference corresponding to a clamp threshold and to determine whether a clamp condition exists. The control portion can be implemented using a transistor threshold behavior in which conduction begins when the sense signal exceeds a selected level, using a transistor pair to increase gain and provide a sharper transition, or using a comparator to provide a more defined switching point. In embodiments that include a comparator, the reference can be provided by a fixed reference generator, a resistor divider, a digital to analog converter, or another adjustable reference source. In some embodiments, the control portion includes hysteresis to reduce chatter near the threshold and to provide a more stable transition into and out of clamping.

In one or more embodiments, the configurable clamping circuit 160 includes an interface portion configured to couple to the control node interface 132 and to selectively alter an effective impedance presented to the control node interface 132 based on the determination by the control portion. In one or more embodiments, the interface portion is implemented using a transistor that, when off, presents a relatively high impedance and, when on, couples the control node interface 132 to a reference potential through a relatively low impedance. In some embodiments, the interface portion is implemented using a transmission gate, an analog switch, a source follower, an emitter follower, or another driver structure that couples a defined bias condition to the control node interface 132 during a clamp condition. In some embodiments, the interface portion includes a resistive element that limits a maximum drive current into the control node interface 132 or that sets a selected effective impedance during clamping. In some embodiments, the interface portion is arranged to apply a defined bias toward a positive supply rail to reduce sourcing capability or toward a negative supply rail to reduce sinking capability.

In some embodiments, the configurable clamping circuit 160 is configured to limit current in one direction by influencing a single high impedance control node 134. In other embodiments, the configurable clamping circuit 160 is configured to limit both sourcing current and sinking current by separately sensing respective currents and selectively influencing respective high impedance control nodes 134 associated with respective output drive directions of the output drive 138. In such embodiments, the configurable clamping circuit 160 can be implemented as two instances of the sense portion, the control portion, and the interface portion, where each instance is coupled to a respective control node interface 132 and is configured to assert clamping in response to an over threshold condition for a corresponding current direction.

The configurable clamping circuit 160 is “configurable” in that it can be set to establish a selected clamp threshold and a selected clamp response for a particular application. For example, the configurable clamping circuit 160 can be configured to clamp at different output current levels by changing a sense impedance, changing a reference level, selecting among multiple reference levels, or adjusting a programmable threshold input. In some embodiments, the configurable clamping circuit 160 can be configured to clamp sourcing current, sinking current, or both, and can be configured to apply different clamp thresholds for different current directions.

In one or more embodiments, the configurable clamping circuit 160 is further “configurable” in that it can be enabled or disabled, and can be configured to provide different clamp behaviors such as a sharper transition into clamping or a softer transition into clamping based on a selected gain, a selected hysteresis amount, or a selected impedance applied at the control node interface 132 during a clamp condition. In some embodiments, configuration is achieved using fixed component selection. In other embodiments, configuration is achieved using a controllable reference signal generated by control circuitry

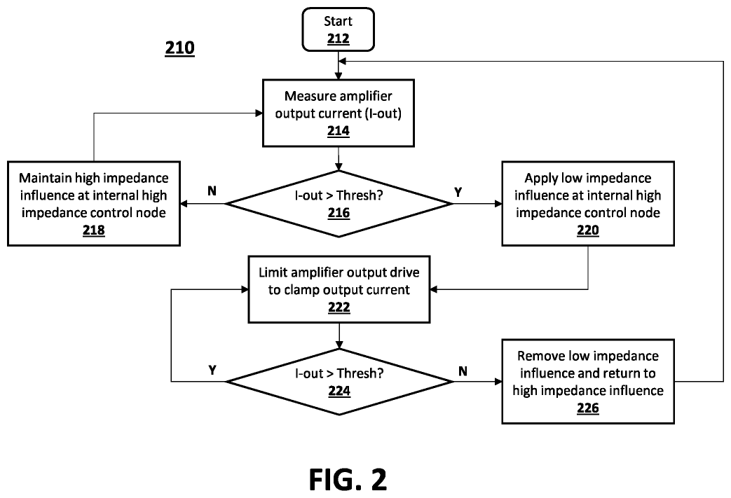

FIG. 2 depicts a method 210 for clamping an amplifier current that can be performed in accordance with one or more embodiments of the disclosure. The method 210 can be performed by the system 110 of FIG. 1, for example by cooperative operation of the amplifier circuit 130 and the configurable clamping circuit 160 coupled to the control node interface 132. The method 210 starts at block 212 them move to block 214. At block 214, the method 210 includes measuring an amplifier output current Iout. In one or more embodiments, the measured current corresponds to a current delivered by the output drive 138 to the load 150 as the load 150 draws a current draw 152. In one or more embodiments, the measurement at block 214 is performed by the configurable clamping circuit 160 using a sense portion that generates a sense signal indicative of the measured current. The sense portion can sense the current in an output path or in a supply path of the amplifier circuit 130, and the sense portion can generate a voltage or current representative of Iout.

At decision block 216, the method 210 determines whether Iout is greater than a threshold. In one or more embodiments, the threshold corresponds to a clamp threshold established by the configurable clamping circuit 160, for example based on a reference level and a sensed signal derived from a sensing element. When the determination at decision block 216 is no, meaning Iout is not greater than the threshold, the method 210 proceeds to block 218. At block 218, the method 210 maintains a high impedance influence at an internal high impedance control node. In one or more embodiments, maintaining the high impedance influence at block 218 includes configuring the configurable clamping circuit 160 to present a relatively high impedance at the control node interface 132 so that the high impedance control node 134 continues to support the amplifier performance shaping function(s) 136 during nominal operation. Following block 218, the method 210 returns to block 214 to continue monitoring Iout.

When the determination at decision block 216 is yes, meaning Iout is greater than the threshold, the method 210 proceeds to block 220. At block 220, the method 210 applies a low impedance influence at the internal high impedance control node 134. In one or more embodiments, applying the low impedance influence at block 220 includes configuring the configurable clamping circuit 160 to present a relatively low impedance to a reference potential at the control node interface 132 so that the high impedance control node 134 is driven toward a corresponding bias level. At block 222, the method 210 limits the output drive 138 to clamp output current. In one or more embodiments, limiting the output drive 138 at block 222 occurs because the bias level at the high impedance control node 134 reduces a drive capability of the output drive 138 so that the output current delivered to the load 150 is constrained near the threshold.

At decision block 224, the method 210 determines whether Iout remains greater than the threshold. When the determination at decision block 224 is yes, the method 210 returns to block 222 to continue limiting the output drive 138 while the clamp condition persists. When the determination at decision block 224 is no, the method 210 proceeds to block 226. At block 226, the method 210 removes the low impedance influence and returns to the high impedance influence. In one or more embodiments, block 226 includes configuring the configurable clamping circuit 160 to return to a state in which a relatively high impedance is presented at the control node interface 132, thereby allowing the high impedance control node 134 to again primarily support the amplifier performance shaping function(s) 136. Following block 226, the method 210 returns to block 214 to continue monitoring Iout.

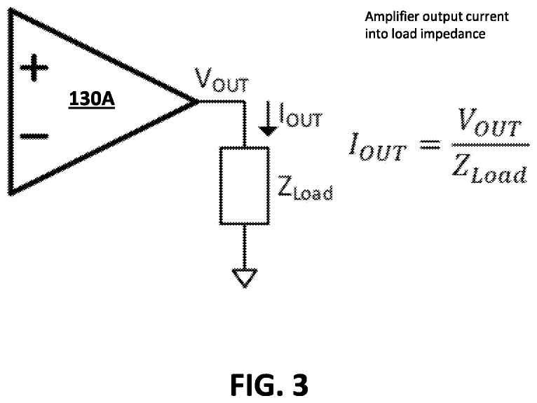

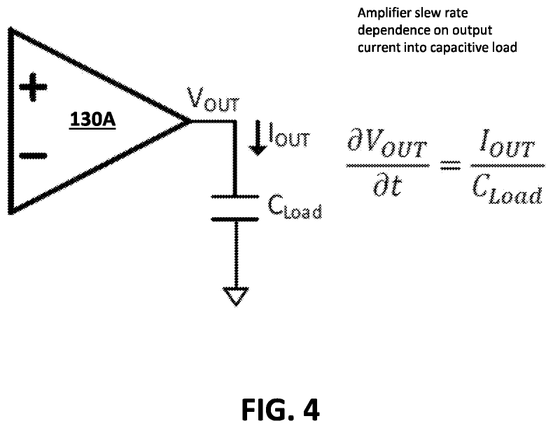

FIGS. 3 and 4 provide simplified circuit diagrams configured to illustrate why limiting or clamping output current can be desirable in practical systems, such as when driving a capacitive load or encountering a low impedance fault. More specifically, FIG. 3 depicts an amplifier 130A having an output node that provides an output voltage Vout to a load having an impedance Z-load. The load is shown coupled to a reference node, and an output current Iout is drawn from the amplifier 130A into the load impedance Zload. FIG. 3 further illustrates that, for a given output Vout, the output current Iout is determined by the impedance of the load, for example according to Iout=Vout/Zload. Accordingly, when the load impedance decreases, such as during a fault event that causes the load to present a low impedance at the output node, the output current drawn from the amplifier 130A can increase substantially.

FIG. 4 depicts an amplifier 130A having an output node that provides an output voltage Vₒᵤₜ to a capacitive load represented by a capacitance C_{load} coupled between the output node and a reference node. An output current Iₒᵤₜ is shown flowing from the amplifier 130A into the capacitive load. FIG. 4 further illustrates that, when driving a capacitive load, the output current Iₒᵤₜ is associated with a rate of change of the output voltage Vₒᵤₜ. For example, the relationship between output current and output voltage slew rate can be expressed as

$$\frac{{dV}_{out}}{dt} = \frac{{I}_{out}}{{C}_{load}} .$$

Accordingly, for a given capacitive load C_{load}, increasing the output current increases the rate at which the output voltage changes, and for a given output current, increasing the capacitive load decreases the rate at which the output voltage changes. In practical systems, a large capacitive load or a transient event that effectively increases capacitive loading can cause the amplifier 130A to demand increased output current to achieve a desired output voltage transition, which can increase stress on output stage devices and can lead to undesirable behavior if the resulting current exceeds a desired operating level.

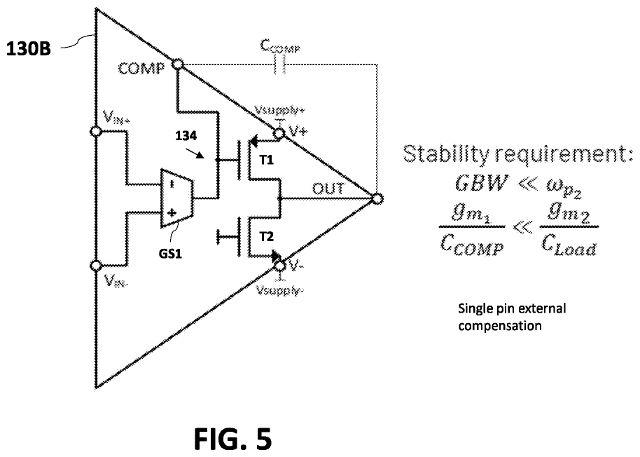

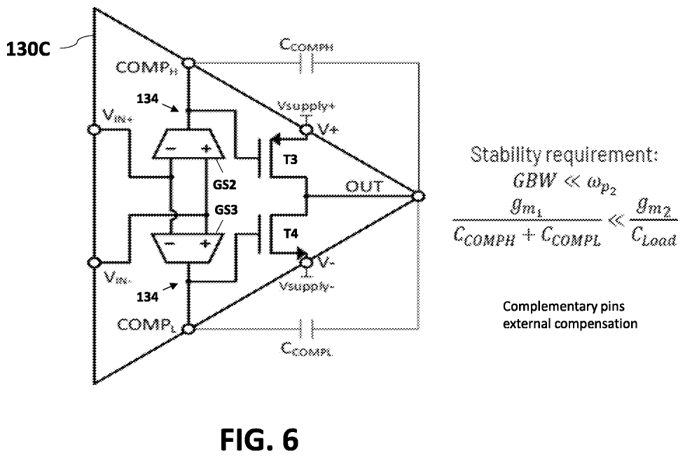

In one or more embodiments, the amplifier circuit 130 of FIG. 1 can be implemented using circuitry that employs compensation to control loop dynamics and to maintain stable operation across a range of gain settings and load conditions. In such implementations, the amplifier performance shaping function(s) 136 include compensation behavior that establishes one or more poles and zeros that contribute to a selected gain bandwidth product and phase margin. When the amplifier drives a load that includes capacitance, an additional load dependent pole can be introduced that is influenced by an effective transconductance of an output stage and the load capacitance. As the effective capacitance at the output increases, the frequency of the load dependent pole can decrease and reduce phase margin, which can degrade stability and increase overshoot or ringing. To address these effects, certain non-limiting examples of the amplifier circuit 130 provide an external interface to an internal high impedance control node so that a user can couple an external impedance that influences the compensation behavior. FIGS. 5 and 6 illustrate representative non-limiting examples of such amplifier implementations and show how externally coupled components can participate in shaping the compensation behavior that is included within the amplifier performance shaping function(s) 136

FIG. 5 depicts an example amplifier 130B that includes differential input terminals V_{IN+} and V_{IN-}, supply terminals V₊ and V₋, and an output terminal OUT. The amplifier 130B further includes internal amplifier circuitry that can include an input stage configured to sense a difference between V_{IN+} and V_{IN-}, one or more gain stages configured to provide amplification, and an output stage that includes one or more output transistors configured to source and sink output current at OUT. FIG. 5 further depicts a high impedance control node within the internal amplifier circuitry, shown coupled to a compensation terminal COMP through an internal connection. In one or more embodiments, the high impedance control node is coupled to a control electrode of at least one output transistor or to an upstream node that influences a drive signal applied to the output stage. In this manner, an impedance coupled to COMP can influence both an amplifier performance shaping function and a drive capability of the output stage. FIG. 5 further depicts an external compensation capacitor C_{COMP} coupled between COMP and OUT, and a load capacitance C_{Load} coupled to OUT. In operation, C_{COMP} can contribute to shaping loop dynamics of the amplifier 130B so that the amplifier 130B remains stable while driving the capacitive load

In one or more embodiments, the amplifier circuit 130 of FIG. 1 can be implemented using circuitry that employs compensation to control loop dynamics and to maintain stable operation across a range of gain settings and load conditions. In such implementations, the amplifier performance shaping function(s) 136 include compensation behavior that establishes one or more poles and zeros that contribute to a selected gain bandwidth product and phase margin. When the amplifier drives a load that includes capacitance, an additional load dependent pole can be introduced that is influenced by an effective transconductance of an output stage and the load capacitance. As the effective capacitance at the output increases, the frequency of the load dependent pole can decrease and reduce phase margin, which can degrade stability and increase overshoot or ringing. To address these effects, certain non-limiting examples of the amplifier circuit 130 provide an external interface to an internal high impedance control node so that a user can couple an external impedance that influences the compensation behavior. FIGS. 5 and 6 illustrate representative non limiting examples of such amplifier implementations and show how externally coupled components can participate in shaping the compensation behavior that is included within the amplifier performance shaping function(s) 136.

FIG. 5 depicts an example amplifier 130B that includes differential input terminals V_{IN+} and V_{IN-}, supply terminals V+ and V−, and an output terminal OUT. The amplifier 130B further includes an internal gain stage GS1 and an output stage that includes transistors T1 and T2 configured to drive the output terminal OUT. FIG. 5 further depicts a compensation terminal COMP that is coupled through internal circuitry of the amplifier 130B to a high impedance control node 134. The high impedance control node 134 is positioned within an internal control path of the amplifier 130B such that a condition at the high impedance control node 134 influences operation of GS1 and further influences how the output stage is driven. FIG. 5 further depicts an external compensation capacitor C_{COMP} coupled between COMP and OUT. Although not depicted separately from OUT, a load capacitance C_{Load} is coupled to OUT. In FIG. 5, positive supply rail Vsupply+ and negative supply rail Vsupply-provide operating power for the amplifier 130B and for the output stage that includes transistors T1 and T2. In one or more embodiments, transistors T1 and T2 are coupled to positive supply rail Vsupply+ and negative supply rail Vsupply−, respectively, such that the output stage can source output current from positive supply rail Vsupply+ toward output terminal OUT and sink output current from output terminal OUT toward negative supply rail Vsupply−.

In the non-limiting illustration of FIG. 5, the stability requirement expressions shown in the figure convey that stable operation can be supported when a loop gain bandwidth product GBW is sufficiently below a higher frequency pole ωₚ₂, as represented by GBW<<ωₚ₂. The expressions further convey a relationship between an effective transconductance parameter gₘ₁ associated with an internal gain stage and an effective transconductance parameter gₘ₂ associated with the output drive, in which a ratio

$$\frac{{g}_{m 1}}{{C}_{COMP}}$$

is sufficiently below a ration

$$\frac{{g}_{m 2}}{{C}_{Load}} ,$$

as represented by

$$\frac{{g}_{m 1}}{{C}_{COMP}} ≪ \frac{{g}_{m 2}}{{C}_{Load}} .$$

In this context, C_{COMP} corresponds to the externally coupled compensation capacitance and C_{Load} corresponds to an effective capacitive loading at OUT. In one or more embodiments, selecting a value of C_{COMP} contributes to the amplifier performance shaping function(s) 136 by conditioning loop dynamics of amplifier 130B for a given range of load capacitances C_{Load}.

FIG. 6 an example amplifier 130C that includes differential input terminals V_{IN+} and V_{IN-}, supply terminals V+ and V−, and an output terminal OUT. The amplifier 130C includes internal gain stages GS2 and GS3 and an output stage that includes transistors T3 and T4 configured to drive the output terminal OUT. FIG. 6 further depicts two compensation terminals, namely COMP_H and COMP_L, which are each coupled through internal circuitry of amplifier 130C to a respective high impedance control node 134. FIG. 6 further depicts external compensation capacitors C_{COMPH} and C_{COMPL} coupled between COMP_H and OUT and between COMP_L and OUT, respectively, and a load capacitance C_{Load} coupled to OUT.

In the non-limiting illustration of FIG. 6, the stability requirement expressions shown in the figure convey that stable operation can be supported when a loop gain bandwidth product GBW is sufficiently below a higher frequency pole ωₚ₂, as represented by GBW<<ωₚ₂. The expressions further convey that the effective compensation capacitance can include a combined contribution from the external capacitors C_{COMPH} and C_{COMPL}. This is represented by a ratio

$$\frac{{g}_{m 1}}{{C}_{COMPH} + {C}_{COMPL}}$$

being sufficiently below a ratio

$$\frac{{g}_{m 2}}{{C}_{Load}} ,$$

as represented by

$$\frac{{g}_{m 1}}{{C}_{COMPH} + {C}_{COMPL}} ≪ \frac{{g}_{m 2}}{{C}_{Load}} .$$

In this context, C_{COMPH}+C_{COMPL} corresponds to a combined compensation capacitance coupled through COMP_H and COMP_L and C_{Load} corresponds to an effective capacitive loading at OUT. In one or more embodiments, selecting values of C_{COMPH} and C_{COMPL} contributes to the amplifier performance shaping function(s) 136 by conditioning loop dynamics of amplifier 130C for a given range of load capacitances C_{Load}.

In FIGS. 5 and 6, the compensation terminals COMP, COMP_H, and COMP_L are externally accessible interfaces that are coupled to internal high impedance control node or nodes 134 within the amplifier. The internal coupling shown in FIGS. 5 and 6 illustrates that these internal high impedance control node or nodes 134 are positioned within internal control paths that influence both internal gain stages and output stage drive. Accordingly, external impedances coupled to the compensation terminals can be selected to influence the amplifier performance shaping function(s) 136 and support stable operation under different gain settings and load conditions, including load conditions that include significant capacitance represented by C_{Load}.

With respect to FIG. 5, in some embodiments, transistor T1 can be implemented as a p-type output transistor and transistor T2 can be implemented as an n-type output transistor. In such embodiments, compensation pin COMP is coupled to high impedance control node 134 associated with gain stage GS1 in a manner that influences the control terminal of transistor T1. This arrangement is consistent with a sourcing output path in which transistor T1 is coupled toward supply terminal V+ and provides output current to output terminal OUT to drive output terminal OUT high, while transistor T2 provides a complementary return path toward supply terminal V−. In these embodiments, driving compensation pin COMP toward a bias condition associated with supply terminal V+ reduces the magnitude of a gate to source voltage of transistor T1 when transistor T1 is a p-type transistor, thereby reducing conduction of transistor T1 and limiting the ability of the amplifier to source output current. Accordingly, transistor T1 can be p-type and transistor T2 can be n-type because the compensation behavior shown in FIG. 5 acts on the upper output path that sources current and drives output terminal OUT high.

With respect to FIG. 6, in some embodiments, transistor T3 can be implemented as a p-type output transistor and transistor T4 can be implemented as an n-type output transistor. In such embodiments, compensation pin COMP_{H} is coupled through high impedance control node 134 and gain stage GS2 to the control terminal of transistor T3, and compensation pin COMP_{L} is coupled through high impedance control node 134 and gain stage GS3 to the control terminal of transistor T4. This arrangement is consistent with transistor T3 being disposed in a high side output path that is coupled toward supply terminal V+ and sources output current at output terminal OUT to drive output terminal OUT high, and with transistor T4 being disposed in a low side output path that is coupled toward supply terminal V− and sinks output current from output terminal OUT to drive output terminal OUT low. In these embodiments, driving compensation pin COMP_{H} toward a bias condition associated with supply terminal V+ reduces the magnitude of a gate to source voltage of transistor T3 when transistor T3 is a p-type output transistor, thereby limiting sourcing current, and driving compensation pin COMP_{L} toward a bias condition associated with supply terminal V− reduces the magnitude of a gate to source voltage of transistor T4 when transistor T4 is an n-type output transistor, thereby limiting sinking current. Accordingly, transistor T3 can be p-type and transistor T4 can be n-type because compensation pin COMP_{H} controls the high side sourcing path and compensation pin COMP_{L} controls the low side sinking path.

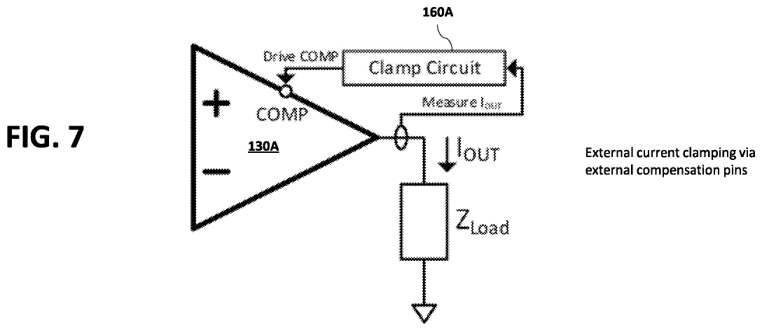

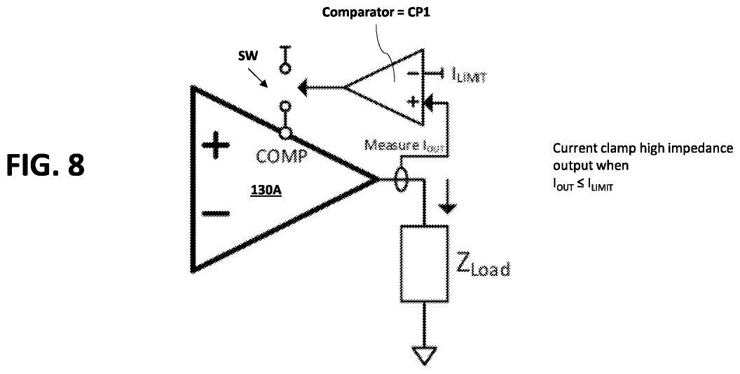

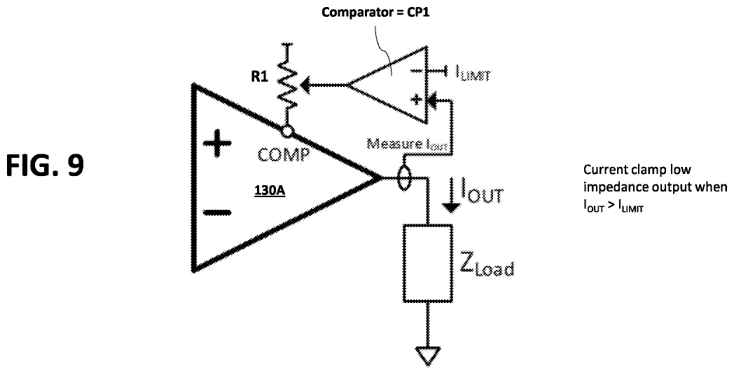

FIGS. 7, 8, and 9 depict non-limiting examples of how the amplifier circuit 130 and configurable clamping circuit 160 can be implemented in accordance with embodiments of the disclosure. More specifically, FIG. 7 depicts an implementation where external clamping is accomplished through compensation pins of an amplifier circuit; FIG. 8 depicts an implementation where the current clamping functionality generates a high impedance output when I_{OUT} is less than or equal to I_{LIMIT}; and FIG. 9 depicts an implementation where the current clamping functionality generates a low impedance output when I_{OUT} is greater than I_{LIMIT}. Turning initially to FIG. 7, it depicts an operational amplifier clamp circuit schematic in which an amplifier 130A drives a load impedance Z_{Load} and delivers an output current I_{OUT} to the load impedance Z_{Load}. The amplifier 130A includes a compensation pin labeled COMP, where COMP is a nonlimiting example implementation of the control node interface 132. In FIG. 7, the amplifier performance shaping function(s) 136 are implemented as compensation behavior that establishes one or more poles and zeros that contribute to a selected gain bandwidth product and phase margin. FIG. 7 further depicts a configurable clamping circuit 160A coupled to the compensation pin COMP. The configurable clamping circuit 160A is a nonlimiting example implementation of the configurable clamping circuit 160 of FIG. 1. In the nonlimiting illustration of FIG. 7, the configurable clamping circuit 160A includes a measure I_{OUT} function that senses information indicative of the output current I_{OUT} and includes a drive COMP function that applies an impedance condition at the compensation pin COMP. In operation, the measure I_{OUT} function and the drive COMP function cooperate so that, responsive to the sensed output current I_{OUT} satisfying a clamp condition, the configurable clamping circuit 160A influences the compensation pin COMP to cause the amplifier 130A to limit the output current I_{OUT} using one or more of the clamping techniques described herein.

FIG. 8 depicts an operational amplifier current clamping schematic in which the amplifier 130A drives the load impedance Z_{Load} and delivers the output current I_{OUT}. The amplifier 130A includes the compensation pin COMP, where the compensation pin COMP is a nonlimiting example implementation of the control node interface 132 and is associated with the compensation behavior of the amplifier performance shaping function(s) 136. FIG. 8 further depicts a comparator CP1, a switch SW, a current limit threshold I_{LIMIT}, and a measure I_{OUT} function. In the nonlimiting illustration of FIG. 8, the comparator CP1, the switch SW, the current limit threshold I_{LIMIT}, and the measure I_{OUT} function collectively provide a nonlimiting example implementation of at least a portion of the configurable clamping circuit 160A. The measure I_{OUT} function provides the comparator CP1 with information indicative of the output current I_{OUT}. The current limit threshold I_{LIMIT} provides the comparator CP1 with a reference corresponding to a clamp level. The comparator CP1 compares the information indicative of the output current I_{OUT} to the current limit threshold I_LIMIT and provides an output that controls the switch SW. The switch SW is coupled to the compensation pin COMP and is configured to change an impedance condition presented at the compensation pin COMP based on the output of the comparator CP1. In operation, when the output current I_{OUT} corresponds to a condition below the current limit threshold I_{LIMIT}, the switch SW maintains a state that does not assert clamping at the compensation pin COMP. When the output current I_{OUT} corresponds to a condition at or above the current limit threshold I_{LIMIT}, the comparator CP1 causes the switch SW to assert a clamping influence at the compensation pin COMP so that the amplifier 130A limits the output current I_{OUT} delivered to the load impedance Z_{Load} using one or more of the clamping techniques described herein.

FIG. 9 depicts an operational amplifier current clamping schematic in which the amplifier 130A drives the load impedance Z_{Load} and delivers the output current I_{OUT}. The amplifier 130A includes the compensation pin COMP, where the compensation pin COMP is a nonlimiting example implementation of the control node interface 132 and is associated with the compensation behavior of the amplifier performance shaping function(s) 136. FIG. 9 further depicts a resistor R1, the comparator CP1, the current limit threshold I_{LIMIT}, and the measure I_{OUT} function. In the nonlimiting illustration of FIG. 9, the comparator CP1, the resistor R1, the current limit threshold I_{LIMIT}, and the measure I_{OUT} function collectively provide a nonlimiting example implementation of at least a portion of the configurable clamping circuit 160A. The measure I_{OUT} function provides the comparator CP1 with information indicative of the output current I_{OUT}. The current limit threshold I_{LIMIT} provides the comparator CP1 with a reference corresponding to a clamp level. The comparator CP1 compares the information indicative of the output current I_{OUT} to the current limit threshold I_{LIMIT} and provides an output. The resistor R1 is coupled to the compensation pin COMP and is configured to establish an impedance path that biases the compensation pin COMP based on the output of the comparator CP1. In operation, when the comparator CP1 indicates that the output current I_{OUT} is below the current limit threshold I_{LIMIT}, the impedance path through the resistor R1 causes the compensation pin COMP to remain in a condition that does not assert clamping. When the comparator CP1 indicates that the output current I_{OUT} is at or above the current limit threshold I_{LIMIT}, the output of the comparator CP1 causes the impedance path through the resistor R1 to drive the compensation pin COMP toward a clamp condition that reduces or eliminates the ability of the amplifier 130A to further increase the output current I_{OUT} delivered to the load impedance Z_{Load} using one or more of the clamping techniques decried herein.

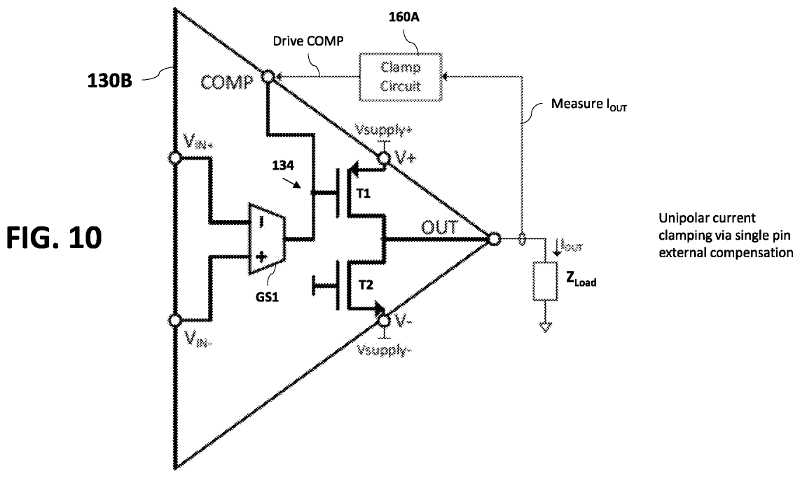

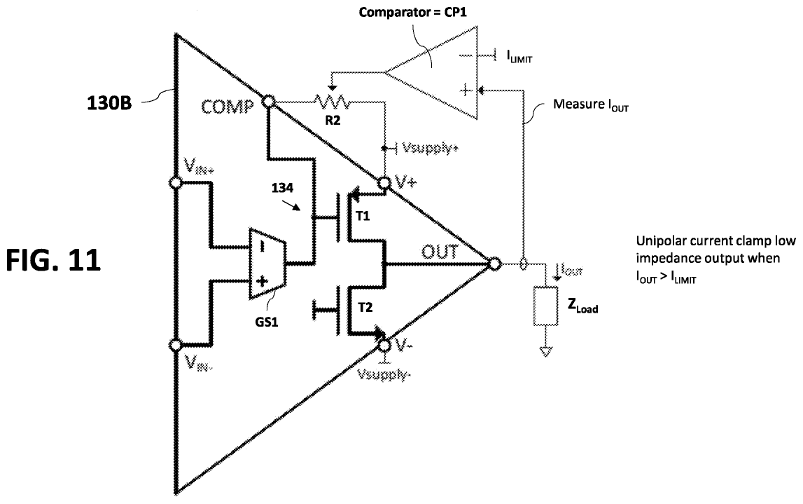

FIGS. 10 and 11 depict non-limiting examples of how the amplifier circuit 130 and configurable clamping circuit 160 can be implemented in accordance with embodiments of the disclosure. More specifically, FIG. 10 depicts unipolar clamping via single pin external compensation; and FIG. 11 depicts unipolar current clamp's low impedance output when I_{OUT} is greater than I_{LIMIT}. Turning initially to FIG. 10, it depicts an operational amplifier with clamp circuit in which amplifier 130B includes compensation pin COMP, input terminal VIN+, input terminal VIN−, gain stage GS1, high impedance control node 134, transistor T1, transistor T2, output terminal OUT, supply terminal V+, supply terminal V−, positive supply rail Vsupply+, and negative supply rail Vsupply−. In the embodiments depicted in FIG. 10, compensation pin COMP is a compensation pin implementation of control node interface 132. In these embodiments, amplifier performance shaping function(s) 136 are implemented as compensation behavior that establishes one or more poles and zeros that contribute to a selected gain bandwidth product and phase margin. FIG. 10 further depicts configurable clamping circuit 160A coupled to compensation pin COMP through a Drive COMP connection. Configurable clamping circuit 160A includes Measure I_{OUT}, where Measure I_{OUT} is coupled to output terminal OUT to obtain information indicative of output current I_{OUT} delivered by output terminal OUT to load impedance Z_{Load}. Load impedance Z_{Load} draws output current I_{OUT} from output terminal OUT. In operation, Measure I_{OUT} of configurable clamping circuit 160A provides information used by configurable clamping circuit 160A to determine when a clamp condition is satisfied, and configurable clamping circuit 160A responsively influences compensation pin COMP through the Drive COMP connection. Because compensation pin COMP is coupled to high impedance control node 134, influencing compensation pin COMP influences high impedance control node 134. High impedance control node 134 is coupled within amplifier 130B such that high impedance control node 134 influences gain stage GS1 and further influences drive applied to transistor T1 and transistor T2. Transistor T1 and transistor T2 cooperate to drive output terminal OUT using positive supply rail Vsupply+ and negative supply rail Vsupply−. Accordingly, configurable clamping circuit 160A provides a nonlimiting example implementation of configurable clamping circuit 160 that limits output current I_{OUT} by conditionally influencing compensation pin COMP and therefore conditionally influencing high impedance control node 134 and output current drive provided through transistor T1 and transistor T2 at output terminal OUT.

In one or more embodiments, gain stage GS1 is configured to generate an internal drive signal that controls conduction of transistor T1 and transistor T2 to regulate a voltage at output terminal OUT. High impedance control node 134 is coupled to gain stage GS1 at an internal control point such that a voltage and or impedance condition at high impedance control node 134 influences at least one operating parameter of gain stage GS1. For example, high impedance control node 134 can influence an effective gain of gain stage GS1, an effective transconductance of gain stage GS1, a bias current of gain stage GS1, or a signal swing of gain stage GS1. By influencing gain stage GS1 in this manner, high impedance control node 134 correspondingly influences the magnitude and rate of change of the internal drive signal that is applied toward the output stage.

In one or more embodiments, transistor T1 and transistor T2 are configured as complementary output transistors that cooperate to drive output terminal OUT. Transistor T1 is coupled to positive supply rail Vsupply+ and is configured to source output current from positive supply rail Vsupply+ toward output terminal OUT. Transistor T2 is coupled to negative supply rail Vsupply− and is configured to sink output current from output terminal OUT toward negative supply rail Vsupply−. Gain stage GS1 is coupled to transistor T1 and transistor T2 such that the internal drive signal generated by gain stage GS1 adjusts conduction of transistor T1 and adjusts conduction of transistor T2 to provide a controlled output voltage and to meet output current demand. Because the high impedance control node 134 influences gain stage GS1, high impedance control node 134 indirectly influences the drive applied to transistor T1 and transistor T2. In one or more embodiments, moving high impedance control node 134 toward a selected bias condition reduces a drive strength provided by gain stage GS1 to transistor T1 and or transistor T2 so that transistor T1 and transistor T2 are inhibited from further increasing output current at output terminal OUT beyond a clamp level while allowing transistor T1 and transistor T2 to continue driving output terminal OUT within a constrained current range.

FIG. 11 depicts an operational amplifier current clamping schematic in which amplifier 130B includes compensation pin COMP, input terminal VIN+, input terminal VIN−, gain stage GS1, high impedance control node 134, transistor T1, transistor T2, output terminal OUT, supply terminal V+, supply terminal V−, positive supply rail Vsupply+, and negative supply rail Vsupply−. FIG. 11 further depicts comparator CP1, resistor R2, current limit threshold I_{LIMIT}, and Measure I_{OUT}. In the embodiments depicted in FIG. 11, compensation pin COMP is a compensation pin implementation of control node interface 132, and amplifier performance shaping function(s) 136 are implemented as compensation behavior that establishes one or more poles and zeros that contribute to a selected gain bandwidth product and phase margin. Measure I_{OUT} is coupled to output terminal OUT to obtain information indicative of output current I_{OUT} delivered to load impedance Z_{Load}. Current limit threshold I_{LIMIT} provides comparator CP1 with a reference corresponding to a clamp level. Comparator CP1 compares Measure I_{OUT} to current limit threshold I_{LIMIT} and provides an output that controls an impedance condition applied through resistor R2. Resistor R2 is coupled between compensation pin COMP and a node driven by comparator CP1 so that an output state of comparator CP1 causes resistor R2 to bias compensation pin COMP toward a clamp bias condition when a clamp condition is present. When output current I_{OUT} is below current limit threshold I_{LIMIT}, comparator CP1 causes compensation pin COMP to remain in a non-clamping condition in which compensation pin COMP does not receive the clamp bias through resistor R2. When output current I_OUT is at or above current limit threshold I_{LIMIT}, comparator CP1 causes compensation pin COMP to be driven through resistor R2 toward the clamp bias condition. Driving compensation pin COMP through resistor R2 influences high impedance control node 134, and high impedance control node 134 influences gain stage GS1 and influences drive applied to transistor T1 and transistor T2. Transistor T1 and transistor T2 thereby reduce or eliminate an ability to further increase output current I_{OUT} delivered at output terminal OUT to load impedance Z_{Load}. In FIG. 11, comparator CP1, current limit threshold I_{LIMIT}, Measure I_{OUT}, and resistor R2 provide a nonlimiting example implementation of configurable clamping circuit 160 that limits output current I_{OUT} by converting Measure I_{OUT} into a conditional bias influence applied at compensation pin COMP.

In one or more of the embodiments depicted in FIG. 11, during non-clamping operation, comparator CP1 indicates that output current I_{OUT} as provided by Measure I_{OUT} is below current limit threshold I_{LIMIT}. In this non-clamping condition, comparator CP1 maintains an output state that causes resistor R2 to avoid pulling compensation pin COMP toward a clamp bias condition. As a result, compensation pin COMP presents a relatively high impedance influence to high impedance control node 134 so that high impedance control node 134 remains primarily governed by internal amplifier conditions and any compensation network coupled to compensation pin COMP. In this state, gain stage GS1 operates to generate an internal drive signal that controls conduction of transistor T1 and transistor T2 to regulate output terminal OUT in accordance with input terminal VIN+ and input terminal VIN−. Transistor T1 sources current from positive supply rail Vsupply+ toward output terminal OUT when output terminal OUT is driven upward, and transistor T2 sinks current from output terminal OUT toward negative supply rail Vsupply− when output terminal OUT is driven downward.

In one or more of the embodiments depicted in FIG. 11, during clamping operation, comparator CP1 indicates that output current I_{OUT} as provided by Measure I_{OUT} is at or above current limit threshold I_{LIMIT}. In this clamping condition, comparator CP1 changes its output state so that resistor R2 establishes a defined bias influence at compensation pin COMP. The bias influence at compensation pin COMP is coupled to high impedance control node 134 and drives high impedance control node 134 toward a bias condition associated with reduced output current drive. Because high impedance control node 134 is coupled to an internal control point of gain stage GS1, the bias condition at high impedance control node 134 changes an operating parameter of gain stage GS1 that affects the internal drive signal applied to transistor T1 and transistor T2. In one or more embodiments, the changed operating parameter reduces an effective transconductance, an effective gain, or an available signal swing of gain stage GS1 so that gain stage GS1 provides less incremental drive to transistor T1 and transistor T2 in the direction that would otherwise increase output current I_OUT.

In one or more of the embodiments, as load impedance Z_{Load} attempts to draw additional output current I_{OUT} while comparator CP1 continues to indicate the clamp condition, the bias condition at high impedance control node 134 causes the internal drive signal from gain stage GS1 to limit further increases in conduction of transistor T1 when sourcing current and or limit further increases in conduction of transistor T2 when sinking current. In this manner, transistor T1 and transistor T2 continue to operate to drive output terminal OUT, but the output stage is inhibited from further increasing output current I_{OUT} beyond a clamp level associated with current limit threshold I_{LIMIT}. When Measure I_{OUT} indicates that output current I_{OUT} has fallen below current limit threshold I_{LIMIT}, comparator CP1 returns to the non-clamping output state so that resistor R2 no longer biases compensation pin COMP toward the clamp bias condition and high impedance control node 134 returns to the non-clamping operating condition.

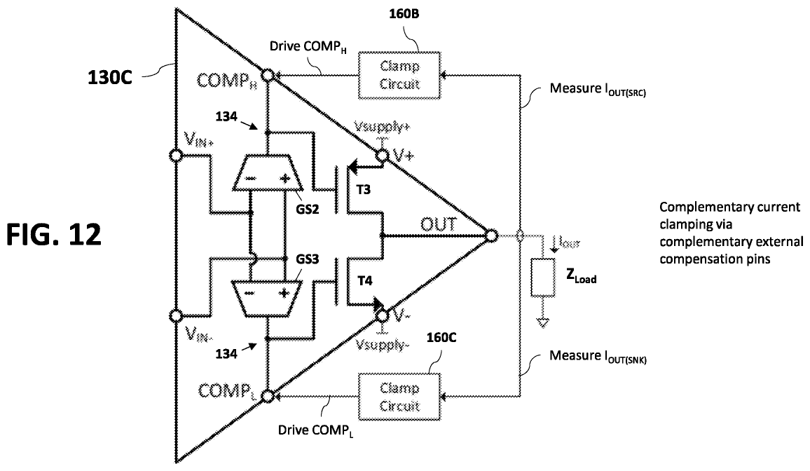

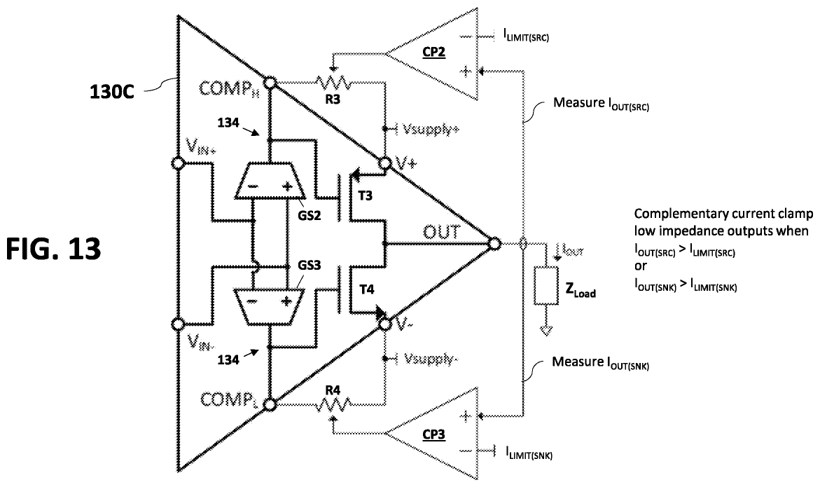

FIGS. 12 and 13 depict non-limiting examples of how the amplifier circuit 130 and configurable clamping circuit 160 can be implemented in accordance with embodiments of the disclosure. More specifically, FIG. 12 depicts complementary current clamping via complementary external compensation pins; and FIG. 13 depicts complementary current clamp low impedance outputs when I_{OUT(SRC)} is greater than I_{LIMIT(SRC)} or when I_{OUT(SNK)} is greater than I_{LIMIT(SNK)}. Turning initially to FIG. 12, it depicts an operational amplifier clamping schematic in which the amplifier 130C drives load impedance Z_{Load} through output terminal OUT and delivers output current I_{OUT} to load impedance Z_{Load}. The amplifier 130C includes compensation pin COMP_{H} and compensation pin COMP_{L}, where compensation pin COMP_{H} and compensation pin COMP_{L} are compensation pin implementations of control node interface 132. In one or more embodiments, compensation pin COMP_{H} and compensation pin COMP_{L} correspond to different internal high impedance control nodes 134 that influence different output drive directions of the amplifier 130C. Compensation pin COMP_{H} is coupled to a high impedance control node 134 associated with a sourcing path that influences transistor T3 so that compensation applied at compensation pin COMP_{H} affects operation when the amplifier 130C drives output terminal OUT toward a higher voltage. Compensation pin COMP_{L} is coupled to a high impedance control node 134 associated with a sinking path that influences transistor T4 so that compensation applied at compensation pin COMP_{L} affects operation when the amplifier 130C drives output terminal OUT toward a lower voltage. In these embodiments, amplifier performance shaping function(s) 136 are implemented as compensation behavior that establishes one or more poles and zeros that contribute to a selected gain bandwidth product and phase margin. The amplifier 130C includes gain stage GS2, gain stage GS3, transistor T3, and transistor T4. The amplifier 130C includes high impedance control node 134 coupled to compensation pin COMP_{H} and high impedance control node 134 coupled to compensation pin COMP_{L}. Gain stage GS2 and gain stage GS3 are coupled to receive input terminal VIN+ and input terminal VIN−. Gain stage GS2 and gain stage GS3 are further coupled to provide internal drive to transistor T3 and transistor T4 to control output terminal OUT. Transistor T3 is coupled to supply node V+ and is further coupled to positive supply rail Vsupply+. Transistor T4 is coupled to supply node V− and is further coupled to negative supply rail Vsupply−. Output terminal OUT is coupled to load impedance Z_{Load} such that load impedance Z_{Load} draws output current I_{OUT} from output terminal OUT.

FIG. 12 further depicts configurable clamping circuit 160B and configurable clamping circuit 160C. Configurable clamping circuit 160B and configurable clamping circuit 160C are nonlimiting example implementations of configurable clamping circuit 160. Configurable clamping circuit 160B is coupled to compensation pin COMP_{H} through a Drive COMP_{H} connection. Configurable clamping circuit 160C is coupled to compensation pin COMP_{L} through a Drive COMP_{L} connection. Configurable clamping circuit 160B includes a Measure I_{OUT(SRC)} function that is configured to obtain information indicative of a sourcing component of output current I_{OUT}, identified as Measure I_{OUT(SRC)}. Configurable clamping circuit 160C includes a Measure I_{OUT(SNK)} function that is configured to obtain information indicative of a sinking component of output current I_{OUT}, identified as Measure I_{OUT(SNK)}. In operation, Measure I_{OUT(SRC)} of configurable clamping circuit 160B and Measure I_{OUT} (SNK) of configurable clamping circuit 160C allow configurable clamping circuit 160B and configurable clamping circuit 160C to determine when respective clamp conditions exist for sourcing current and sinking current. In response, configurable clamping circuit 160B can influence compensation pin COMP_{H} and configurable clamping circuit 160C can influence compensation pin COMP_{L} so that amplifier 130C limits output current I_{OUT}.

In FIG. 12, high impedance control node 134 coupled to compensation pin COMP_{H} is coupled within amplifier 130C such that high impedance control node 134 influences gain stage GS2 and further influences a drive condition applied to transistor T3. In FIG. 12, high impedance control node 134 coupled to compensation pin COMP_{L} is coupled within amplifier 130C such that high impedance control node 134 influences gain stage GS3 and further influences a drive condition applied to transistor T4. Gain stage GS2 is coupled to transistor T3 so that gain stage GS2 controls conduction of transistor T3 to source current from positive supply rail Vsupply+ toward output terminal OUT when load impedance Z_{Load} draws output current I_{OUT} in a sourcing direction. Gain stage GS3 is coupled to transistor T4 so that gain stage GS3 controls conduction of transistor T4 to sink current from output terminal OUT toward negative supply rail Vsupply-when load impedance Z_{Load} draws output current I_{OUT} in a sinking direction. Because compensation pin COMP_{H} is coupled to high impedance control node 134 that influences gain stage GS2 and transistor T3, driving compensation pin COMP_{H} by configurable clamping circuit 160B changes a condition at high impedance control node 134 that reduces an ability of gain stage GS2 to further increase conduction of transistor T3 when Measure I_{OUT(SRC)} indicates that sourcing current satisfies a clamp condition. Because compensation pin COMP_{L} is coupled to high impedance control node 134 that influences gain stage GS3 and transistor T4, driving compensation pin COMP_{L} by configurable clamping circuit 160C changes a condition at high impedance control node 134 that reduces an ability of gain stage GS3 to further increase conduction of transistor T4 when Measure I_{OUT(SNK)} indicates that sinking current satisfies a clamp condition. In this manner, configurable clamping circuit 160B and configurable clamping circuit 160C provide a complementary non limiting example of how configurable clamping circuit 160 can be implemented to limit sourcing and sinking components of output current I_{OUT} by influencing compensation pin COMP_{H} and compensation pin COMP_{L}.

FIG. 13 depicts an operational amplifier current clamping schematic that provides a more detailed nonlimiting example implementation of configurable clamping circuit 160 for an amplifier having compensation pin COMP_{H} and compensation pin COMP_{L}. FIG. 13 includes amplifier 130C, compensation pin COMP_{H}, compensation pin COMP_{L}, input terminal V_{IN+}, input terminal V_{IN-}, output terminal OUT, load impedance Z_{Load}, output current I_{OUT}, gain stage GS2, gain stage GS3, transistor T3, transistor T4, and high impedance control node 134 coupled to compensation pin COMP_{H} and high impedance control node 134 coupled to compensation pin COMP_{L}. FIG. 13 further includes comparator CP2, comparator CP3, resistor R3, resistor R4, Measure I_{OUT(SRC)}, Measure I_{OUT(SNK)}, current limit I_{LIMIT(SRC)}, and current limit I_{LIMIT(SNK)}. Comparator CP2, resistor R3, Measure I_{OUT(SRC)}, and current limit I_{LIMIT} (SRC) provide a nonlimiting example implementation of a portion of configurable clamping circuit 160 that influences compensation pin COMP_{H}. Comparator CP3, resistor R4, Measure I_{OUT(SNK)}, and current limit I_{LIMIT} (SNK) provide a nonlimiting example implementation of a portion of configurable clamping circuit 160 that influences compensation pin COMP_{L}.

In FIG. 13, Measure I_{OUT(SRC)} provides comparator CP2 with information indicative of sourcing current associated with output current I_{OUT}. Current limit I_{LIMIT(SRC)} provides comparator CP2 with a reference corresponding to a sourcing clamp threshold. Comparator CP2 compares Measure I_{OUT(SRC)} to current limit I_{LIMIT(SRC)} and provides an output that controls a bias influence applied through resistor R3. Resistor R3 is coupled to compensation pin COMP_{H} so that the output of comparator CP2, through resistor R3, conditionally drives compensation pin COMP_{H} toward a clamp bias condition when Measure I_{OUT(SRC)} satisfies a clamp condition relative to current limit I_{LIMIT(SRC)}. Driving compensation pin COMP_{H} through resistor R3 influences high impedance control node 134 coupled to compensation pin COMP_{H}, which influences gain stage GS2 and influences a drive condition applied to transistor T3 so that transistor T3 is inhibited from further increasing sourcing current associated with output current I_{OUT}.

In FIG. 13, Measure I_{OUT(SNK)} provides comparator CP3 with information indicative of sinking current associated with output current I_{OUT}. Current limit I_{LIMIT(SNK)} provides comparator CP3 with a reference corresponding to a sinking clamp threshold. Comparator CP3 compares Measure I_{OUT(SNK)} to current limit I_{LIMIT(SNK)} and provides an output that controls a bias influence applied through resistor R4. Resistor R4 is coupled to compensation pin COMP_{L} so that the output of comparator CP3, through resistor R4, conditionally drives compensation pin COMP_{L} toward a clamp bias condition when Measure I_{OUT(SNK)} satisfies a clamp condition relative to current limit I_{LIMIT(SNK)}. Driving compensation pin COMP_{L} through resistor R4 influences high impedance control node 134 coupled to compensation pin COMP_{L}, which influences gain stage GS3 and influences a drive condition applied to transistor T4 so that transistor T4 is inhibited from further increasing sinking current associated with output current I_{OUT}.

In FIG. 13, during non-clamping operation, comparator CP2 and comparator CP3 maintain output states that cause resistor R3 and resistor R4 to avoid driving compensation pin COMP_{H} and compensation pin COMP_{L} toward clamp bias conditions, which allows high impedance control node 134 coupled to compensation pin COMP_{H} and high impedance control node 134 coupled to compensation pin COMP_{L} to continue supporting compensation behavior included in amplifier performance shaping function(s) 136. During clamping operation, comparator CP2 and comparator CP3 assert output states that, through resistor R3 and resistor R4, impose bias conditions on compensation pin COMP_{H} and compensation pin COMP_{L} that drive high impedance control node 134 coupled to compensation pin COMP_{H} and high impedance control node 134 coupled to compensation pin COMP_{L} toward clamp conditions. Those clamp conditions reduce an ability of gain stage GS2 and gain stage GS3 to further increase conduction of transistor T3 and transistor T4 in the direction that would otherwise increase output current I_{OUT}. In this manner, the nonlimiting example implementations of FIG. 12 and FIG. 13 illustrate how configurable clamping circuit 160 can interface with compensation pin COMP_{H} and compensation pin COMP_{L} to cause amplifier 130C to provide clamping functionality while compensation pin COMP_{H} and compensation pin COMP_{L} remain associated with compensation behavior that establishes one or more poles and zeros that contribute to a selected gain bandwidth product and phase margin.

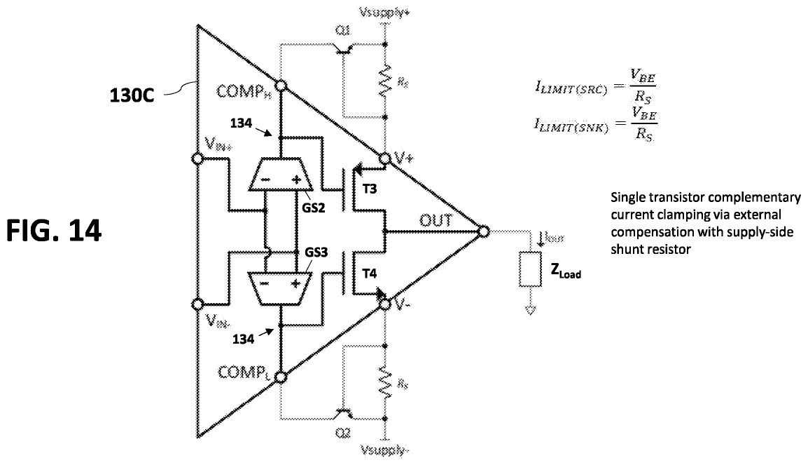

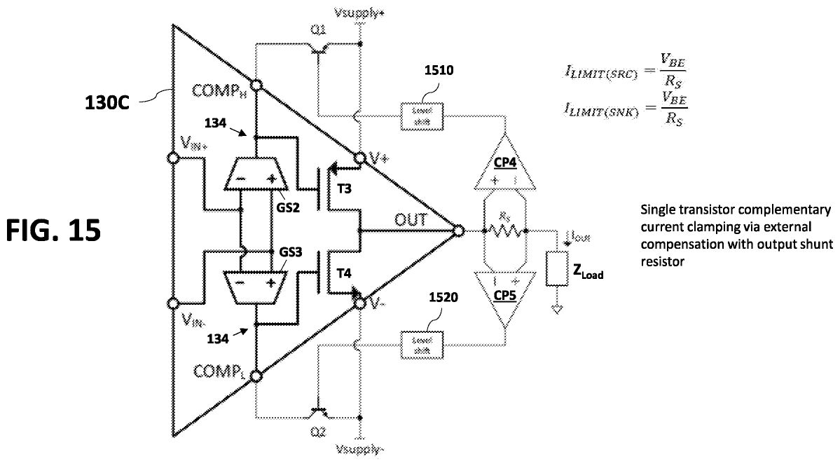

FIGS. 14 and 15 depict non-limiting examples of how the amplifier circuit 130 and configurable clamping circuit 160 can be implemented in accordance with embodiments of the disclosure. More specifically, FIG. 14 depicts single transistor complementary current clamping via external compensation with supply-side shunt resistor; and FIG. 15 depicts single transistor complementary current clamping via external compensation with output shunt resistor. Turning initially to FIG. 14, it depicts an operational amplifier current clamping schematic in which amplifier 130C includes compensation pin COMP_{H} and compensation pin COMP_{L}, input terminal V_{IN+} and input terminal V_{IN-}, supply terminal V+ and supply terminal V−, output terminal OUT, gain stage GS2, gain stage GS3, transistor T3, transistor T4, and high impedance control node 134. Compensation pin COMP_{H} and compensation pin COMP_{L} are compensation pin implementations of control node interface 132. In these embodiments, amplifier performance shaping function(s) 136 are implemented as compensation behavior that establishes one or more poles and zeros that contribute to a selected gain bandwidth product and phase margin. Output terminal OUT is coupled to load impedance Z_{Load} such that load impedance Z_{Load} draws output current I_{OUT}.

FIG. 14 further depicts positive supply rail Vsupply+ and negative supply rail Vsupply−, sense resistor R_{S}, transistor Q1, and transistor Q2. Sense resistor R_{S} is coupled in a supply path between positive supply rail Vsupply+ and supply terminal V+ and sense resistor R_{S} is coupled in a supply path between negative supply rail Vsupply− and supply terminal V−. Transistor Q1 is coupled to sense resistor R_{S} associated with positive supply rail Vsupply+ and supply terminal V+ and transistor Q1 is coupled to compensation pin COMP_{H}. Transistor Q2 is coupled to sense resistor R_{S} associated with negative supply rail Vsupply− and supply terminal V− and transistor Q2 is coupled to compensation pin COMP_{L}. In one or more embodiments, sense resistor R_{S}, transistor Q1, and transistor Q2 provide a non-limiting example implementation of configurable clamping circuit 160 in which a voltage developed across sense resistor R_{S} due to supply current is used to control conduction of transistor Q1 and transistor Q2. In one or more embodiments, transistor Q1 and transistor Q2 present a relatively high impedance to compensation pin COMP_{H} and compensation pin COMP_{L} when a corresponding sensed current is below a clamp threshold and transistor Q1 and transistor Q2 present a relatively low impedance to a corresponding reference potential when the corresponding sensed current satisfies a clamp condition.

In the non-limiting illustration of FIG. 14, the equations I_{LIMIT(SRC)}=(V_{BE}/R_{S}) and I_{LIMIT(SNK)}=(V_{BE}/R_{S}) express example relationships for clamp thresholds associated with a sourcing direction and a sinking direction, respectively. In these expressions, R_{S} corresponds to sense resistor R_{S} and V_{BE} corresponds to a base emitter voltage associated with a bipolar transistor implementation, such as transistor Q1 and transistor Q2. The equations convey that a clamp threshold current is set, at least in part, by a ratio of a transistor base emitter voltage to the resistance value of sense resistor R_{S}, such that selecting a different value for sense resistor R_{S} changes the corresponding clamp threshold current.

With respect to the circuitry of FIG. 14, sense resistor R_{S} is positioned so that a current associated with the sourcing path produces a voltage across sense resistor R_{S} that is applied to transistor Q1 and a current associated with the sinking path produces a voltage across sense resistor R_{S} that is applied to transistor Q2. When the voltage developed across sense resistor R_{S} approaches the base emitter voltage V_{BE} of transistor Q1 or transistor Q2, the corresponding transistor begins to conduct and provides a low impedance influence at compensation pin COMP_{H} or compensation pin COMP_{L}. Through the coupling between compensation pin COMP_{H} and the corresponding high impedance control node 134, and between compensation pin COMP_{L} and the corresponding high impedance control node 134, conduction of transistor Q1 and transistor Q2 drives the high impedance control node 134 toward a bias condition that reduces the ability of gain stage GS2 and gain stage GS3 to further increase conduction of transistor T3 and transistor T4. As a result, output current I_{OUT} is constrained in the sourcing direction and the sinking direction relative to the clamp thresholds represented by I_{LIMIT(SRC)} and I_{LIMIT(SNK)}.

FIG. 15 depicts an operational amplifier current clamping schematic in which amplifier 130C includes compensation pin COMP_{H} and compensation pin COMP_{L}, input terminal V_{IN+} and input terminal V_{IN-}, output terminal OUT, gain stage GS2, gain stage GS3, transistor T3, transistor T4, and high impedance control node 134. Compensation pin COMP_{H} and compensation pin COMP_{L} are compensation pin implementations of control node interface 132. In these embodiments, amplifier performance shaping function(s) 136 are implemented as compensation behavior that establishes one or more poles and zeros that contribute to a selected gain bandwidth product and phase margin. Output terminal OUT is coupled to load impedance Z_{Load} such that load impedance Z_{Load} draws output current I_{OUT}.

FIG. 15 further depicts sense resistor R_S, comparator CP4, comparator CP5, level shift 1510, level shift 1520, transistor Q1, and transistor Q2. Sense resistor R_{S} is coupled in an output path associated with output terminal OUT such that a voltage across sense resistor R_{S} corresponds to output current I_{OUT}. Comparator CP4 is coupled to sense resistor R_{S} to determine a sourcing current condition associated with output current I_{OUT} and comparator CP5 is coupled to sense resistor R_{S} to determine a sinking current condition associated with output current I_{OUT}. Level shift 1510 is coupled between comparator CP4 and transistor Q1 and level shift 1520 is coupled between comparator CP5 and transistor Q2. Transistor Q1 is coupled to compensation pin COMP_{H} and transistor Q2 is coupled to compensation pin COMP_{L}. In one or more embodiments, sense resistor R_{S}, comparator CP4, comparator CP5, level shift 1510, level shift 1520, transistor Q1, and transistor Q2 provide a non-limiting example implementation of configurable clamping circuit 160 in which comparator CP4 and comparator CP5 generate clamp control states based on the voltage across sense resistor R_{S} and level shift 1510 and level shift 1520 translate the clamp control states for application at transistor Q1 and transistor Q2. Level shift 1510 and level shift 1520 translate the output of comparator CP4 and comparator CP5 into a voltage domain that can properly drive transistor Q1 and transistor Q2, respectively, given where Q1 and Q2 sit relative to the amplifier supply rails and the compensation pins. In one or more embodiments, transistor Q1 and transistor Q2 present a relatively high impedance to compensation pin COMP_{H} and compensation pin COMP_{L} when comparator CP4 and comparator CP5 indicate a non-clamping condition and transistor Q1 and transistor Q2 present a relatively low impedance to a corresponding reference potential when comparator CP4 and comparator CP5 indicate a clamp condition.

In FIG. 15, high impedance control node 134 coupled to compensation pin COMP_{H} is coupled to gain stage GS2 and is further coupled within amplifier 130C to a control path that drives transistor T3, and high impedance control node 134 coupled to compensation pin COMP_{L} is coupled to gain stage GS3 and is further coupled within amplifier 130C to a control path that drives transistor T4. During non-clamping operation, comparator CP4 and comparator CP5 cause transistor Q1 and transistor Q2 to avoid driving compensation pin COMP_{H} and compensation pin COMP_{L} toward clamp bias conditions, and gain stage GS2 and gain stage GS3 control transistor T3 and transistor T4 to drive output terminal OUT in response to input terminal V_{IN+} and input terminal V_{IN-}. During clamping operation for sourcing current, comparator CP4 causes transistor Q1 to drive compensation pin COMP_{H} so that high impedance control node 134 coupled to compensation pin COMP_{H} is biased to reduce an ability of gain stage GS2 to further increase conduction of transistor T3. During clamping operation for sinking current, comparator CP5 causes transistor Q2 to drive compensation pin COMP_{L} so that high impedance control node 134 coupled to compensation pin COMP_{L} is biased to reduce an ability of gain stage GS3 to further increase conduction of transistor T4. As a result, amplifier 130C constrains output current I_{OUT} delivered at output terminal OUT while maintaining operation of gain stage GS2, gain stage GS3, transistor T3, and transistor T4 within the clamp condition.

In the non-limiting illustration of FIG. 15, the equations I_{LIMIT(SRC)}=(V_{BE}/R_{S}) and I_{LIMIT(SNK)}=(V_{BE}/R_{S}) express example relationships for clamp thresholds associated with a sourcing direction and a sinking direction, respectively. In these expressions, R_{S} corresponds to sense resistor R_{S} and V_{BE} corresponds to a base emitter voltage associated with a bipolar transistor implementation, such as transistor Q1 and transistor Q2. The equations convey that a clamp threshold current is set, at least in part, by a ratio of a transistor base emitter voltage to the resistance value of sense resistor R_{S}, such that selecting a different value for sense resistor R_{S} changes the corresponding clamp threshold current.

With respect to the circuitry of FIG. 15, sense resistor R_{S} is coupled in an output path associated with output terminal OUT so that output current I_{OUT} produces a voltage across sense resistor R_{S}. Comparator CP4 and comparator CP5 evaluate the voltage across sense resistor R_{S} to determine whether the sourcing component of output current I_{OUT} or the sinking component of output current I_{OUT} satisfies a clamp condition. In one or more embodiments, the clamp condition corresponds to the voltage across sense resistor R_{S} approaching a threshold associated with V_{BE} such that when |I_{OUT}|R_{S} reaches a level corresponding V_{BE}, comparator CP4 or comparator CP5 causes transistor Q1 or transistor Q2 to transition to a conduction state. Level shift 1510 and level shift 1520 couple the comparator outputs to transistor Q1 and transistor Q2 so that, when the clamp condition is satisfied, transistor Q1 drives compensation pin COMP_{H} and transistor Q2 drives compensation pin COMP_{L}. Driving compensation pin COMP_{H} and compensation pin COMP_{L} influences the corresponding high impedance control node 134 and reduces the ability of gain stage GS2 and gain stage GS3 to further increase conduction of transistor T3 and transistor T4, thereby constraining output current I_{OUT} in accordance with the clamp thresholds represented by equations I_{LIMIT(SRC)} and I_{LIMIT(SNK)}.

Level shift 1510 and level shift 1520 translate the output of comparator CP4 and comparator CP5 into a voltage domain that can properly drive transistor Q1 and transistor Q2, respectively, given where Q1 and Q2 sit relative to the amplifier supply rails and the compensation pins. In FIG. 15, comparator CP4 and comparator CP5 sense the voltage across sense resistor R_{S} at the output path, which is referenced to the output common mode and can move over a wide range with OUT. Transistor Q1 and transistor Q2, however, are arranged to act on compensation pin COMP_{H} and compensation pin COMP_{L} near the positive supply and the negative supply, respectively. Level shift 1510 and level shift 1520 therefore provide a shifted control signal that preserves the clamp decision made by comparator CP4 or comparator CP5 while re-referencing that control signal so it can turn on or turn off transistor Q1 or transistor Q2 with the required polarity and headroom. As a result, level shift 1510 allows the clamp decision for sourcing current to be asserted at transistor Q1 in the high side domain, and level shift 1520 allows the clamp decision for sinking current to be asserted at transistor Q2 in the low side domain. This avoids relying on the comparators to directly swing to the high side or low side rails and supports reliable switching of Q1 and Q2 even when OUT is at a different potential than the supply referenced nodes used to influence COMP_{H} and COMP_{L}.

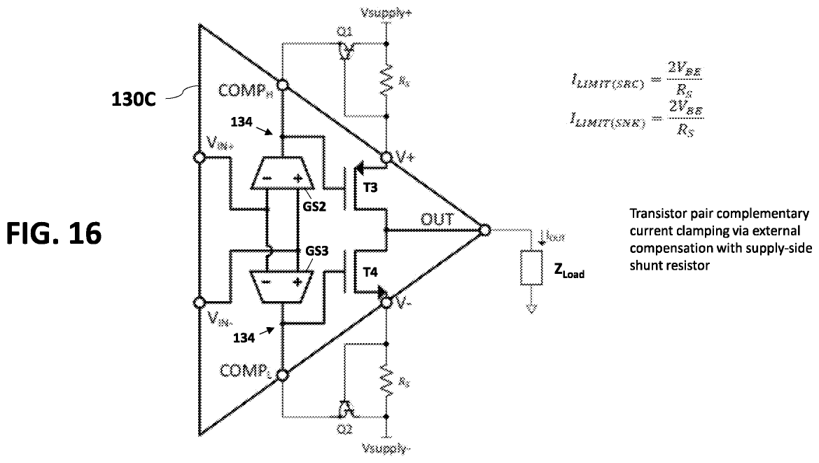

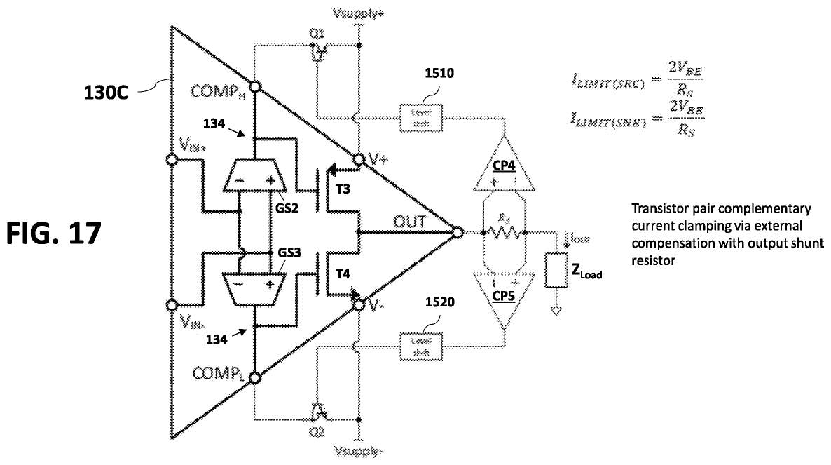

FIGS. 16 and 17 depict non-limiting examples of how the amplifier circuit 130 and configurable clamping circuit 160 can be implemented in accordance with embodiments of the disclosure. More specifically, FIG. 16 depicts transistor pair complementary current clamping via external compensation with supply-side shunt resistor; and FIG. 17 depicts transistor pair complementary current clamping via external compensation with output shunt resistor. Turning initially to FIG. 16, it depicts an operational amplifier current clamping schematic in which amplifier 130C includes compensation pin COMP_{H} and compensation pin COMP_{L}, input terminal V_{IN+} and input terminal V_{IN-}, supply terminal V+ and supply terminal V−, and output terminal OUT. Compensation pin COMP_{H} and compensation pin COMP_{L} are compensation pin implementations of control node interface 132. In these embodiments, amplifier performance shaping function(s) 136 are implemented as compensation behavior that establishes one or more poles and zeros that contribute to a selected gain bandwidth product and phase margin. Output terminal OUT is coupled to load impedance Z_{Load} such that load impedance Z_{Load} draws output current I_{OUT}. Amplifier 130C includes gain stage GS2, gain stage GS3, transistor T3, and transistor T4, and amplifier 130C further includes high impedance control node 134 coupled to compensation pin COMP_{H} and high impedance control node 134 coupled to compensation pin COMP_{L}. Gain stage GS2 and gain stage GS3 receive input terminal V_{IN+} and input terminal V_{IN-} and cooperate to provide internal drive that controls conduction of transistor T3 and transistor T4 to regulate output terminal OUT. Transistor T3 is coupled to supply terminal V+ and transistor T4 is coupled to supply terminal V−, and transistor T3 and transistor T4 cooperate to source and sink output current I_{OUT} for load impedance Z_{Load}.

FIG. 16 further depicts positive supply rail Vsupply+, negative supply rail Vsupply−, sense resistor R_{S}, transistor Q1, and transistor Q2. Sense resistor R_{S} is positioned in a supply path so that a current associated with the sourcing path develops a voltage across sense resistor R_{S} associated with positive supply rail Vsupply+, and a current associated with the sinking path develops a voltage across sense resistor R_{S} associated with negative supply rail Vsupply−. Transistor Q1 is coupled to sense resistor R_{S} and is coupled to compensation pin COMP_{H} so that conduction of transistor Q1 changes an impedance condition presented at compensation pin COMP_{H}. Transistor Q2 is coupled to sense resistor R_{S} and is coupled to compensation pin COMP_{L} so that conduction of transistor Q2 changes an impedance condition presented at compensation pin COMP_{L}. In FIG. 16, transistor Q1 and transistor Q2 are shown in a special configuration in which each of transistor Q1 and transistor Q2 includes a two junction bipolar arrangement that presents two base emitter junction drops in the sensing path, which causes conduction to begin when the voltage across sense resistor R_{S} approaches approximately 2V_{BE}. In one or more embodiments, this two junction bipolar arrangement is implemented using a transistor pair such as a Darlington pair or a Sziklai pair, or another two transistor configuration that produces an effective turn on corresponding to two base emitter junctions

In the non-limiting illustration of FIG. 16, the equations I_{LIMIT(SRC)}=(2V_{BE}/R_{S}) and I_{LIMIT(SNK)}=(2V_{BE}/R_{S}) express example relationships for clamp thresholds associated with sourcing current and sinking current. In these expressions, R_{S} corresponds to sense resistor R_{S} and V_{BE} corresponds to a base emitter voltage of a bipolar junction. The factor of 2 reflects that transistor Q1 and transistor Q2 in FIG. 16 employ the two junction bipolar arrangement so that the turn on condition corresponds to approximately 2V_{BE} across sense resistor R_{S}. Selecting a value for sense resistor R_{S} therefore establishes the sourcing clamp threshold I_{LIMIT(SRC)} and the sinking clamp threshold I_{LIMIT(SNK)} in accordance with the expressions. When the sourcing current produces a voltage across sense resistor R_{S} that reaches the turn on level, transistor Q1 conducts and presents a low impedance influence at compensation pin COMP_{H}, thereby driving high impedance control node 134 coupled to compensation pin COMP_{H} toward a bias condition that reduces the ability of gain stage GS2 to further increase drive applied to transistor T3. When the sinking current produces a voltage across sense resistor R_{S} that reaches the turn on level, transistor Q2 conducts and presents a low impedance influence at compensation pin COMP_{L}, thereby driving high impedance control node 134 coupled to compensation pin COMP_{L} toward a bias condition that reduces the ability of gain stage GS3 to further increase drive applied to transistor T4. In this manner, the illustrated arrangement provides a non-limiting example implementation of configurable clamping circuit 160 in which sense resistor R_{S} and transistor Q1 and transistor Q2 cooperate to limit further increase of output current I_{OUT} through output terminal OUT.

FIG. 17 depicts an operational amplifier current clamping schematic in which amplifier 130C includes compensation pin COMP_{H} and compensation pin COMP_{L}, input terminal V_{IN+} and input terminal V_{IN-}, supply terminal V+ and supply terminal V−, and output terminal OUT. Compensation pin COMP_{H} and compensation pin COMP_{L} are compensation pin implementations of control node interface 132. In these embodiments, amplifier performance shaping function(s) 136 are implemented as compensation behavior that establishes one or more poles and zeros that contribute to a selected gain bandwidth product and phase margin. Output terminal OUT is coupled to load impedance Z_{Load} such that load impedance Z_{Load} draws output current I_{OUT}. Amplifier 130C includes gain stage GS2, gain stage GS3, transistor T3, and transistor T4, and amplifier 130C further includes high impedance control node 134 coupled to compensation pin COMP_{H} and high impedance control node 134 coupled to compensation pin COMP_{L}. Gain stage GS2 and gain stage GS3 receive input terminal V_{IN+} and input terminal V_{IN-} and provide internal drive that controls conduction of transistor T3 and transistor T4 to regulate output terminal OUT.

FIG. 17 further depicts sense resistor R_{S}, comparator CP4, comparator CP5, level shift 1510, level shift 1520, transistor Q1, transistor Q2, level shift 1510, and level shift 1520. Sense resistor R_{S} is positioned in an output path so that output current I_{OUT} produces a voltage across sense resistor R_{S}. Comparator CP4 and comparator CP5 evaluate the voltage across sense resistor R_{S} to determine whether a sourcing clamp condition or a sinking clamp condition is present. Transistor Q1 is coupled to compensation pin COMP_{H} and transistor Q2 is coupled to compensation pin COMP_{L}. Transistor Q1 and transistor Q2 are shown in a special configuration in which each of transistor Q1 and transistor Q2 includes a two junction bipolar arrangement that presents two base emitter junction drops in the control path, which corresponds to an effective turn on associated with approximately 2V_{BE}. In one or more embodiments, the two junction bipolar arrangement for transistor Q1 and the two junction bipolar arrangement for transistor Q2 are implemented using a transistor pair such as a Darlington pair or a Sziklai pair, or another two transistor configuration that produces an effective turn on corresponding to two base emitter junctions.

Level shift 1510 is coupled between comparator CP4 and transistor Q1, and level shift 1520 is coupled between comparator CP5 and transistor Q2. Level shift 1510 and level shift 1520 translate the output states produced by comparator CP4 and comparator CP5 into voltage domains suitable for controlling conduction of transistor Q1 and transistor Q2, respectively, given that comparator CP4 and comparator CP5 operate based on the voltage across sense resistor R_{S} in the output path while transistor Q1 and transistor Q2 act at compensation pin COMP_{H} and compensation pin COMP_{L} near supply referenced internal control paths of amplifier 130C. Level shift 1510 preserves the clamp decision of comparator CP4 while re referencing the control signal to provide appropriate polarity and headroom to turn transistor Q1 on or off. Level shift 1520 preserves the clamp decision of comparator CP5 while re referencing the control signal to provide appropriate polarity and headroom to turn transistor Q2 on or off. In one or more embodiments, level shift 1510 and level shift 1520 provide isolation between the output referenced sensing portion and the supply referenced drive portion so that transistor Q1 and transistor Q2 can be reliably controlled even as output terminal OUT moves over a wide voltage range.

In the non-limiting illustration of FIG. 17, the equations I_{LIMIT(SRC)}=(2V_{BE}/R_{S}) and I_{LIMIT(SNK)}=(2V_{BE}/R_{S}) express example relationships for clamp thresholds associated with sourcing current and sinking current. In these expressions, R_{S} corresponds to sense resistor R_{S} and V_{BE} corresponds to a base emitter voltage of a bipolar junction. The factor of 2 reflects that transistor Q1 and transistor Q2 in FIG. 17 employ the two junction bipolar arrangement so that the effective clamp transition corresponds to approximately 2V_{BE} across sense resistor R_{S}. Selecting a value for sense resistor R_{S} therefore establishes the sourcing clamp threshold I_{LIMIT(SRC)} and the sinking clamp threshold I_{LIMIT(SNK)}. When comparator CP4 determines that the sourcing component of output current I_{OUT} produces a voltage across sense resistor R_{S} corresponding to the sourcing clamp threshold, comparator CP4 changes state and, through level shift 1510, turns on transistor Q1 so that transistor Q1 presents a low impedance influence at compensation pin COMP_{H}. The low impedance influence at compensation pin COMP_{H} drives high impedance control node 134 coupled to compensation pin COMP_{H} toward a bias condition that reduces the ability of gain stage GS2 to further increase drive applied to transistor T3, thereby constraining sourcing current. When comparator CP5 determines that the sinking component of output current I_{OUT} produces a voltage across sense resistor R_{S} corresponding to the sinking clamp threshold, comparator CP5 changes state and, through level shift 1520, turns on transistor Q2 so that transistor Q2 presents a low impedance influence at compensation pin COMP_{L}. The low impedance influence at compensation pin COMP_{L} drives high impedance control node 134 coupled to compensation pin COMP_{L} toward a bias condition that reduces the ability of gain stage GS3 to further increase drive applied to transistor T4, thereby constraining sinking current. In this manner, sense resistor R_{S}, comparator CP4, comparator CP5, level shift 1510, level shift 1520, transistor Q1, and transistor Q2 provide a non-limiting example implementation of configurable clamping circuit 160 that limits output current I_{OUT} by conditionally influencing compensation pin COMP_{H} and compensation pin COMP_{L} while amplifier 130C continues to perform compensation behavior within amplifier performance shaping function(s) 136.

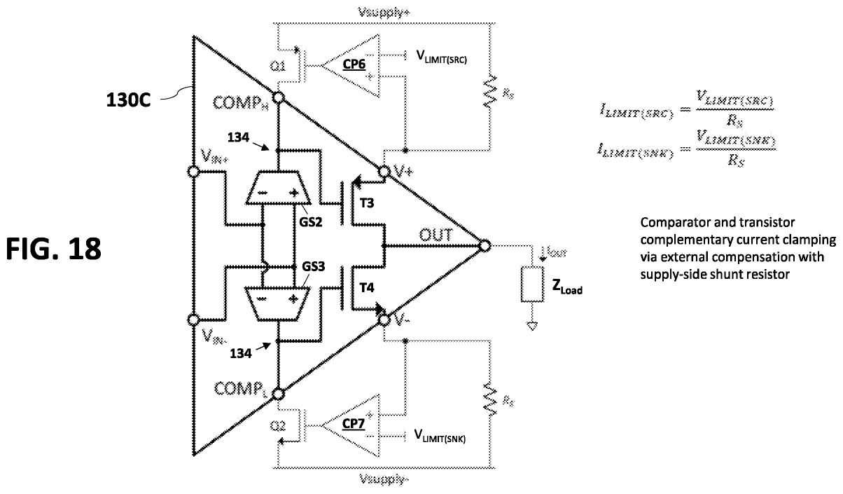

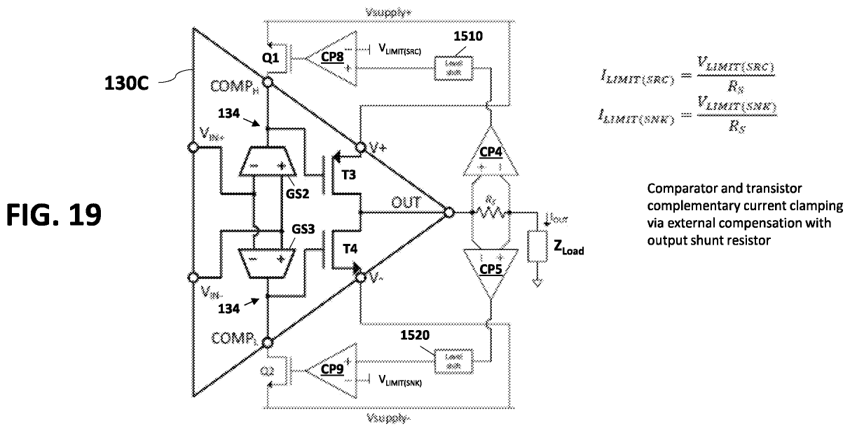

FIGS. 18 and 19 depict non-limiting examples of how the amplifier circuit 130 and configurable clamping circuit 160 can be implemented in accordance with embodiments of the disclosure. More specifically, FIG. 18 depicts comparator and transistor complementary current clamping via external compensation with supply-side shunt resistor; and FIG. 19 depicts comparator and transistor complementary current clamping via external compensation with output shunt resistor. Turning initially to FIG. 18, it depicts an operational amplifier current clamping schematic in which amplifier 130C includes input terminal V_{IN+} and input terminal V_{IN-}, supply terminal V+ and supply terminal V−, output terminal OUT, compensation pin COMP_{H}, compensation pin COMP_{L}, gain stage GS2, gain stage GS3, transistor T3, transistor T4, and high impedance control node 134. In the embodiments of FIG. 18, compensation pin COMP_{H} and compensation pin COMP_{L} are compensation pin implementations of control node interface 132. In these embodiments, amplifier performance shaping function(s) 136 are implemented as compensation behavior that establishes one or more poles and zeros that contribute to a selected gain bandwidth product and phase margin. Output terminal OUT is coupled to load impedance Z_{Load}, and load impedance Z_{Load} draws output current I_{OUT}. Amplifier 130C further includes an internal coupling between compensation pin COMP_{H} and high impedance control node 134 and an internal coupling between compensation pin COMP_{L} and high impedance control node 134. High impedance control node 134 is coupled within amplifier 130C so that high impedance control node 134 influences operation of gain stage GS2 and gain stage GS3 and further influences drive applied to transistor T3 and transistor T4. Transistor T3, and transistor T4 cooperate to drive output terminal OUT, where transistor T3 is associated with a sourcing path from supply terminal V+ toward output terminal OUT and transistor T4 is associated with a sinking path from output terminal OUT toward supply terminal V−. In this arrangement, conditions at compensation pin COMP_{H} and compensation pin COMP_{L} influence high impedance control node 134, and high impedance control node 134 influences how gain stage GS2 and gain stage GS3 drive transistor T3 and transistor T4.

FIG. 8 further depicts a non-limiting example implementation of configurable clamping circuit 160 that includes sense resistor R_{S}, comparator CP6, comparator CP7, voltage limit V_{LIMIT(SRC)}, voltage limit V_{LIMIT(SNK)}, transistor Q1, and transistor Q2. Sense resistor R_{S} is coupled in a positive supply path associated with V+ and is also coupled in a negative supply path associated with V−. Sense resistor R_{S} develops a voltage related to current associated with the positive supply path and develops a voltage related to current associated with the negative supply path. Comparator CP6 is coupled to sense resistor R_{S} in the positive supply path and comparator CP6 is coupled to voltage limit V_{LIMIT(SRC)}. Comparator CP7 is coupled to sense resistor R_{S} in the negative supply path and comparator CP7 is coupled to voltage limit V_{LIMIT(SNK)}. Comparator CP6 provides an output that controls transistor Q1, and transistor Q1 is coupled to compensation pin COMP_{H} so that transistor Q1 conditionally changes an impedance condition presented at compensation pin COMP_{H}. Comparator CP7 provides an output that controls transistor Q2, and transistor Q2 is coupled to compensation pin COMP_{L} so that transistor Q2 conditionally changes an impedance condition presented at compensation pin COMP_{L}. During a non-clamping condition, transistor Q1 and transistor Q2 can be maintained in a state that presents a relatively high impedance at compensation pin COMP_{H} and compensation pin COMP_{L}. During a clamping condition, transistor Q1 and transistor Q2 can be driven to present a relatively low impedance that biases compensation pin COMP_{H} and compensation pin COMP_{L} toward a clamp bias condition

FIG. 18 further includes an equation I_{LIMIT(SRC)}=(V_{LIMIT(SRC)}/R_{S}); and an equation I_{LIMIT(SNK)}=(V_{LIMIT(SNK)}/R_{S}). In equation I_{LIMIT(SRC)}=(V_{LIMIT(SRC)}/R_{S}), voltage limit V_{LIMIT(SRC)} corresponds to a selectable sourcing limit reference and sense resistor R_{S} corresponds to the sensing element that converts a current associated with the positive supply path into a voltage used by comparator CP6. In this non limiting example, selecting voltage limit V_{LIMIT(SRC)} and selecting sense resistor R_{S} set a sourcing current limit I_{LIMIT(SRC)} that is used by comparator CP6 to control transistor Q1 and thereby control the impedance condition at compensation pin COMP_{H}. In the equation I_{LIMIT(SNK)}=(V_{LIMIT(SNK)}/R_{S}), V_{LIMIT(SNK)} corresponds to a selectable sinking limit reference used by comparator CP7 in connection with the sensing arrangement that includes sense resistor R_{S} so that comparator CP7 controls transistor Q2 and thereby controls the impedance condition at compensation pin COMP_{L} for a sinking clamp condition. When transistor Q1 drives compensation pin COMP_{H} toward the clamp bias condition, high impedance control node 134 is driven toward a bias condition that reduces an ability of gain stage GS2 to further increase drive applied to transistor T3 so that transistor T3 is inhibited from further increasing a sourcing component of output current I_{OUT}. When transistor Q2 drives compensation pin COMP_{L} toward the clamp bias condition, high impedance control node 134 is driven toward a bias condition that reduces an ability of gain stage GS3 to further increase drive applied to transistor T4 so that transistor T4 is inhibited from further increasing a sinking component of output current I_{OUT}.

FIG. 19 depicts a circuit diagram for current clamping in which amplifier 130C includes input terminal V_{IN+} and input terminal V_{IN-}, supply terminal V+ and supply terminal V−, output terminal OUT, compensation pin COMP_{H}, compensation pin COMP_{L}, gain stage GS2, gain stage GS3, transistor T3, transistor T4, and high impedance control node 134. In the embodiments depicted in FIG. 19, compensation pin COMP_{H} and compensation pin COMP_{L} are compensation pin implementations of control node interface 132, and amplifier performance shaping function(s) 136 are implemented as compensation behavior that establishes one or more poles and zeros that contribute to a selected gain bandwidth product and phase margin. Output terminal OUT is coupled to load impedance Z_{Load}, and load impedance Z_{Load} draws output current I_{OUT}. Sense resistor R_{S} is coupled in an output current path so that output current I_{OUT} develops a sense voltage across sense resistor R_{S}. Comparator CP4 and comparator CP5 are coupled to sense resistor R_{S} so that comparator CP4 and comparator CP5 evaluate the sense voltage across sense resistor R_{S} in connection with sourcing and sinking conditions associated with output current I_{OUT}. Comparator CP4 is coupled to level shift 1510, and comparator CP5 is coupled to level shift 1520.

Level shift 1510 and level shift 1520 translate information produced by comparator CP4 and comparator CP5 from an output referenced domain associated with output terminal OUT and sense resistor R_{S} into a supply referenced domain used by subsequent clamp decision and clamp drive circuitry. Level shift 1510 provides a translated representation of an output state of comparator CP4 to comparator CP8 so that comparator CP8 can operate with voltage limit V_{LIMIT(SRC)} while remaining referenced to a domain suitable for controlling transistor Q1. Level shift 1520 provides a translated representation of an output state of comparator CP5 to comparator CP9 so that comparator CP9 can operate with voltage limit V_{LIMIT(SNK)} while remaining referenced to a domain suitable for controlling transistor Q2. In this manner, level shift 1510 and level shift 1520 preserve the clamp indication associated with sense resistor R_{S} while providing appropriate polarity and headroom for the high side and low side clamp paths that drive compensation pin COMP_{H} and compensation pin COMP_{L}.

FIG. 19 further depicts comparator CP8, comparator CP9, voltage limit V_{LIMIT(SRC)}, voltage limit V_{LIMIT(SNK)}, transistor Q1, and transistor Q2 as a non-limiting example implementation of configurable clamping circuit 160. Comparator CP8 receives voltage limit V_{LIMIT(SRC)} and receives a translated input from level shift 1510, and comparator CP8 provides an output that controls transistor Q1. Transistor Q1 is coupled to compensation pin COMP_{H} so that transistor Q1 conditionally changes an impedance condition presented at compensation pin COMP_{H}. Comparator CP9 receives voltage limit V_{LIMIT(SNK)} and receives a translated input from level shift 1520, and comparator CP9 provides an output that controls transistor Q2. Transistor Q2 is coupled to compensation pin COMP_{L} so that transistor Q2 conditionally changes an impedance condition presented at compensation pin COMP_{L}. During a non-clamping condition, transistor Q1 and transistor Q2 can be maintained in a state that presents a relatively high impedance at compensation pin COMP_{H} and compensation pin COMP_{L}. During a clamping condition, transistor Q1 and transistor Q2 can be driven to present a relatively low impedance that biases compensation pin COMP_{H} and compensation pin COMP_{L} toward clamp bias conditions

FIG. 19 further includes an equation I_{LIMIT(SRC)}=(V_{LIMIT(SRC)}/R_{S}); and an equation I_{LIMIT(SNK)}=(V_{LIMIT(SNK)}/R_{S}). In equation I_{LIMIT(SRC)}=(V_{LIMIT(SRC)}/R_{S}), voltage limit V_{LIMIT(SRC)} corresponds to a selectable sourcing limit reference and sense resistor R_{S} corresponds to the sensing element that converts output current I_{OUT} into a sense voltage used by comparator CP4, level shift 1510, and comparator CP8. In this non limiting example, selecting voltage limit V_{LIMIT(SRC)} and selecting sense resistor R_{S} set a sourcing current limit I_{LIMIT} (SRC) that is used by comparator CP8 to control transistor Q1 and thereby control the impedance condition at compensation pin COMP_{H}. In the equation I_{LIMIT(SNK)}=(V_{LIMIT(SNK)}/R_{S}), voltage limit V_{LIMIT(SNK)} corresponds to a selectable sinking limit reference used by comparator CP9 in connection with the sensing arrangement that includes sense resistor R_{S}, comparator CP5, and level shift 1520 so that comparator CP9 controls transistor Q2 and thereby controls the impedance condition at compensation pin COMP_{L} for a sinking clamp condition. When transistor Q1 drives compensation pin COMP_{H} toward a clamp bias condition, high impedance control node 134 is driven toward a bias condition that reduces an ability of gain stage GS2 to further increase drive applied to transistor T3 so that transistor T3 is inhibited from further increasing a sourcing component of output current I_{OUT}. When transistor Q2 drives compensation pin COMP_{L} toward a clamp bias condition, high impedance control node 134 is driven toward a bias condition that reduces an ability of gain stage GS3 to further increase drive applied to transistor T4 so that transistor T4 is inhibited from further increasing a sinking component of output current I_{OUT}. In this manner, comparator CP4, comparator CP5, comparator CP8, comparator CP9, level shift 1510, level shift 1520, sense resistor R_{S}, voltage limit V_{LIMIT(SRC)}, voltage limit V_{LIMIT(SNK)}, transistor Q1, and transistor Q2 provide a non-limiting example implementation of configurable clamping circuit 160 that uses selectable voltage limit V_{LIMIT(SRC)} and selectable voltage limit V_{LIMIT(SNK)} to establish clamping thresholds while clamping is applied through compensation pin COMP_{H} and compensation pin COMP_{L} that are associated with compensation behavior included within amplifier performance shaping function(s) 136.

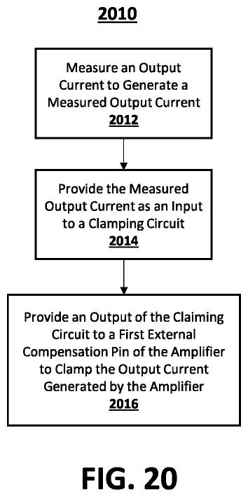

Turning now to FIG. 20, one embodiment of a method for clamping an output circuit of an amplifier is shown. The components embodied in any of the apparatuses or systems previously described above may generally operate in accordance with method 2000. In addition, the steps in this embodiment are shown in sequential order. However, some steps may occur in a different order than shown, some steps may be performed concurrently, some steps may be combined with other steps, and some steps may be absent in another embodiment.

A measure of output current of an amplifier is measured in order to generate a measured current (block 2005). Next, the measured current is provided as an input to a clamping circuit (block 2010). Then, an output of the clamping circuit is provided to a first external compensation pin of the amplifier to clamp the output current generated by the amplifier (block 2015). In other words, the output of the clamping circuit causes the output current generated by the amplifier to be clamped (i.e., limited to a threshold current value). In some embodiments, the threshold current value is a programmable value that may be programmed by software. After block 2015, method 2000 may end.

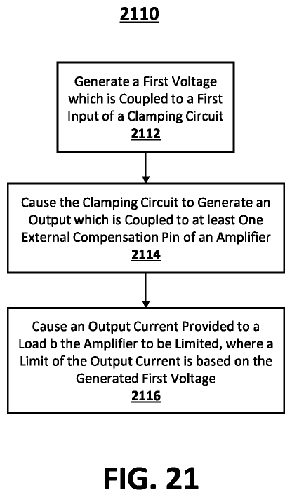

Referring now to FIG. 21, one embodiment of a method for employing software control of current clamping via external compensation is shown. The components embodied in any of the apparatuses or systems previously described above may generally operate in accordance with method 2100. In addition, the steps in this embodiment are shown in sequential order. However, some steps may occur in a different order than shown, some steps may be performed concurrently, some steps may be combined with other steps, and some steps may be absent in another embodiment.

A processing unit (e.g., microprocessor, digital signal processor (DSP), central processing unit (CPU)) generates a first voltage which is coupled to a first input of a clamping circuit (block 2105). The first voltage generated by the processing unit causes the clamping circuit to generate an output which is coupled to at least one external compensation pin of an amplifier (block 2110). The output from the clamping circuit causes an output current provided to a load by the amplifier to be limited, where a limit of the output current is based on the generated first voltage (block 2115). After block 2115, method 2100 may end.

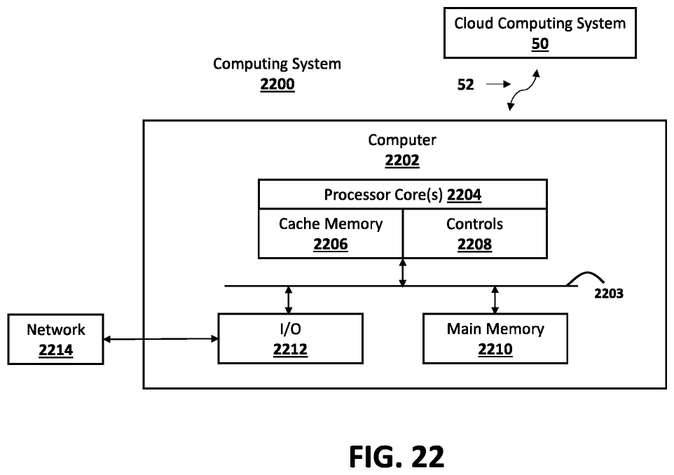

FIG. 22 illustrates an example of a computer system (or processor system) 2200 that is used to implement the computer-based components in accordance with aspects of the disclosure. The computer system 2200 includes an exemplary computing device (“computer”) 2202 configured to perform various aspects of the control operations described herein in accordance with aspects of the disclosure. In addition to computer 2202, the exemplary computer system 2200 includes network 2214, which connects computer 2202 to additional systems (not depicted) and includes one or more wide area networks (WANs) and/or local area networks (LANs) such as the Internet, intranet(s), and/or wireless communication network(s). Computer 2202 and additional system are in communication via network 2214, e.g., to communicate data between them.

Exemplary computer 2202 includes processor cores 2204, main memory (“memory”) 2210, and input/output component(s) 2212, which are in communication via bus 2203. Processor cores 2204 include cache memory (“cache”) 2206 and controls 2208, which include branch prediction structures and associated search, hit, detect and update logic, which will be described in more detail below. Cache 2206 includes multiple cache levels (not depicted) that are on or off-chip from the processor cores 2204. Memory 2210 includes various data stored therein, e.g., instructions, software, routines, etc., which, e.g., are transferred to/from cache 2206 by controls 2208 for execution by the processor cores 2204. Input/output component(s) 2212 include one or more components that facilitate local and/or remote input/output operations to/from computer 2202, such as a display, keyboard, modem, network adapter, etc. (not depicted).

The cloud computing system 50 is in wired or wireless electronic communication with the computer system 2200 over a network communications pathway 52. The cloud computing system 50 includes one or more cloud servers and other computing components that, in some embodiments, supplement, support or replace some or all of the functionality (in any combination) of the computer system 2200. Additionally, some or all of the functionality of the computer system 2200 are, in some embodiments, implemented as a node of the cloud computing system 50.

Accordingly, it can be seen from the foregoing detailed description that embodiments of the disclosure provide technical benefits and technical effects. More specifically, amplifiers commonly use external compensation to control the frequency response and stability of the amplifier. When an amplifier is internally compensated, the internal poles and zeros of the amplifier are fixed. Driving a capacitive load introduces a pole with a frequency determined by the transconductance of the output stage and the capacitance of the load. When a large capacitive load is present, the pole reduces in frequency and will reduce the phase margin of the amplifier, ultimately degrading the stability of the amplifier. The usage of external compensation allows for the amplifier user to stabilize the amplifier by reducing the gain bandwidth product (GBW), improving the phase margin and stability of the amplifier to enable the amplifier to drive large capacitive loads.

An external compensation pin is a high impedance (High Z) node of the amplifier which is connected to an external pin. In other words, the external compensation pin is externally accessible outside of the packaging of the amplifier. In amplifier products, cases of external compensation pins being used include at least the following: Single pin external compensation with compensation pin COMP is conventionally used to compensate the amplifier with a Miller capacitor C_{COMP} from COMP to OUT or from COMP to GND, as shown in FIG. 5. Also, as shown in FIG. 6, complementary pins external compensation with external compensation pins COMP_{H} and COMP_{L} is conventionally used to compensate the amplifier with Miller capacitors C_{COMPH} and C_{COMPL} from COMP_{H} to OUT and COMP_{L} to OUT, respectively.

In one or more embodiments, the external compensation pins are used in an unconventional way, accessing the High Z nodes of the external compensation pins to clamp the output current of the amplifier. In one or more embodiments, amplifiers with supporting external compensation pins are employed. In one or more embodiments, external current clamping is enabled on an amplifier with supporting external compensation pins, as shown in FIG. 7.

In one or more embodiments, a clamp circuit is implemented from I_{OUT} to COMP pin(s). It is noted that the terms “clamp circuit” and “clamping circuit” may be used interchangeably herein. The input is one or more measurements of the output current (I_{OUT}) of the amplifier, either directly or indirectly via supply current. The output is one or more compensation pins (COMP) of the amplifier, corresponding to internal high impedance nodes. In one embodiment, the transfer function of this circuit is: if the measured current is at or below the current clamp threshold, the clamp circuit output is high impedance at COMP, as shown in FIG. 8. If the measured current is above the current clamp threshold I_{LIMIT}, the clamp circuit output is low impedance at COMP to a DC voltage which impedes the amplifier ability to deliver output current. In this state, the clamp circuit has an output impedance which decreases as the output current measurement in excess of the limit (I_{OUT}−I_{LIMIT}), as shown in FIG. 9.

In one or more embodiments, the methods and mechanisms described herein may be applied to different external compensation pins: Single pin external compensation: one-sided current clamping, as shown in FIG. 10 and FIG. 11. Complementary pins external compensation: complementary current clamping, as shown in FIG. 12 and FIG. 13.

In one or more embodiments, multiple implementations of this circuit may be employed, including, but not limited to, the following: Single transistor configuration (FIG. 14 and FIG. 15), Transistor pair configuration (FIG. 16 and FIG. 17), and Comparator and transistor configuration (FIG. 18 and FIG. 19).

In single pin external compensation, a high impedance node controlling the ability of the amplifier to drive the output voltage in one direction and drive current in one direction is connected to the external compensation pin COMP. In one or more embodiments, current clamping is achieved by measuring output current I_{OUT} and driving compensation pin COMP to achieve one-sided current clamping of the amplifier output current, as shown in FIG. 10. Pin COMP connects to the gate of the PMOS output transistor. This gate controls the ability of the amplifier to source output current and drive the output high.

If the measured current is above the current clamp threshold I_{LIMIT}, the clamp circuit output is low impedance at COMP to the positive supply V+. This will reduce the |V_{GS}| of the output PMOS transistor, which will limit the amplifier ability to source output current, as shown in FIG. 11. This circuit has no effect on the amplifier ability to sink output current, hence the current clamping is one-sided. In complementary pins external compensation, two high impedance nodes controlling the ability of the amplifier to drive the output voltage in each direction and drive current in each direction are connected to the external compensation pins COMP_{H} and COMP_{L}.

In one or more embodiments, current clamping is achieved by measuring sourcing output current I_{OUT(SRC)} and sinking output current I_{OUT(SNK)} and driving compensation pins COMP_{H} and COMP_{L} to achieve complementary current clamping of the amplifier output current, as shown in FIG. 12. In this scenario, pin COMP_{H} connects to the gate of the PMOS output transistor. This gate controls the ability of the amplifier source output current and drive the output high. In a complementary fashion, pin COMP_{L} connects to the gate of the NMOS output transistor. This gate controls the ability of the amplifier to source output current and drive the output low.

If the measured sourcing output current is above the current clamp threshold I_{LIMIT(SRC)}, the clamp circuit output is low impedance at COMP_{H} to the positive supply V+. This will reduce the |V_{GS}| of the output PMOS transistor, which will limit the amplifier ability to source output current. If the measured sinking output current is above current clamp threshold I_{LIMIT(SNK)}, the clamp circuit output is low impedance at COMP_{L} to the negative supply V−. This will reduce the |V_{GS}| of the output NMOS transistor, which will limit the amplifier ability to sink output current, as shown in FIG. 13. This circuit enables independent control of the amplifier ability to both source and sink output current, hence the current clamping is complementary.

One implementation that may be employed is the usage of a single transistor (BJT or MOSFET) to implement current clamping via the amplifier external compensation pin(s). This is one possible implementation of the current clamp circuit. If the current clamp on each of the external compensation pins is implemented using a BJT (Q1 and Q2), the current limit threshold is

$${I}_{LIMIT} = \frac{{V}_{BE}}{{R}_{S}} .$$

This current limit threshold could be set independently for the source and sink current directions by using different sense resistors or different transistor V_{BE}. However, in this case the current limit threshold has a temperature drift due to V_{BE} dependence.

A shunt resistor may be used to measure the output current. The voltage across the shunt resistor is used to drive the high impedance input of a transistor (BJT base or MOSFET gate). The transistor output (BJT collector or MOSFET drain) connects from the compensation pin COMP to a DC voltage. If the voltage across the shunt resistor is below the threshold, the output of the transistor will be high impedance. The amplifier output drive and output current will be unaffected.

If the voltage across the shunt resistor is above the threshold, the output of the transistor will be low impedance, driving the amplifier high-Z node. The output drive will be suppressed, and the output current will be clamped. This implementation may use a supply shunt resistor as shown in FIG. 14, which has the benefit of a simpler circuit with low voltage components as well as independent control of source and sink thresholds. However, the shunt resistors will carry both output current and supply current of the amplifier, which is an error source for the current measurement of the output current.

This implementation may instead use an output shunt resistor as shown in FIG. 15 with improved accuracy because the shunt resistor will carry only the amplifier output current. However, the implementation is more complex, requiring higher voltage difference amplifiers for the current measurement as well as level-shifters to reference the voltage to the supply rails.

One implementation may use a transistor pair (Darlington, Sziklai, or BJT and MOSFET) to implement current clamping via the amplifier external compensation pin(s). This is an alternate implementation of the current clamp circuit. The benefit of the transistor pair over the single transistor configuration is improved current gain (β) and higher input impedance. If the current clamp on each of the external compensation pins is implemented using a Darlington pair (Q1 and Q2), the current limit threshold is

$${I}_{LIMIT} = \frac{2 {V}_{BE}}{{R}_{S}} .$$

This current limit threshold could be set independently for the source and sink current directions by using different sense resistors or different transistor V_{BE}. Again, in this case the current limit threshold has a temperature drift due to V_{BE} dependence.

A shunt resistor may be used to measure the output current. The voltage across the shunt resistor is used to drive the high impedance input of the transistor pair. The transistor pair output connects from the compensation pin COMP to a DC voltage. If the voltage across the shunt resistor is below the threshold, the output of the transistor pair will be high impedance. The amplifier output drive and output current will be unaffected. If the voltage across the shunt resistor is above the threshold, the output of the transistor pair will be low impedance, driving the amplifier high-Z node. The output drive will be suppressed, and the output current will be clamped.

This implementation, as shown in FIG. 16, may use a supply shunt resistor with simpler circuit of low voltage components as well as independent control of source and sink thresholds. However, the shunt resistors will carry both output current and supply current of the amplifier, which is an error source for the current measurement of the output current.

This implementation, as shown in FIG. 17, may instead use an output shunt resistor with improved accuracy because the shunt resistor will carry only the amplifier output current. However, the implementation is more complex, requiring higher voltage difference amplifiers for the current measurement as well as level-shifters to reference the voltage to the supply rails.

One implementation may use a comparator and transistor (BJT or MOSFET) to implement current clamping via the amplifier external compensation pin(s). This implementation is a relatively high accuracy and is a programmable version of the proposed current clamp circuit. This circuit has very high gain and high input impedance due to the comparator driving the transistor.

The current limit threshold is set by an input voltage V_{LIMIT}. The current limit threshold may be set independently for the source and sink output currents at thresholds V_{LIMIT(SRC)} and V_{LIMIT(SNK)}, respectively.

A shunt resistor may be used to measure the output current. The voltage across the shunt resistor is used to drive the high impedance input of the comparator. The transistor output (BJT collector or MOSFET drain) connects from the compensation pin COMP to a DC voltage.

If the voltage across the shunt resistor is below the threshold, the output of the transistor will be high impedance. The amplifier output drive and output current will be unaffected. If the voltage across the shunt resistor is above the threshold, the output of the transistor pair will be low impedance, driving the amplifier high-Z node. The output drive will be suppressed, and the output current will be clamped. This implementation may use a supply shunt resistor with a circuit of low voltage components as well as independent control of source and sink thresholds, as shown in FIG. 18. However, the shunt resistors will carry both output current and supply current of the amplifier, which is an error source for the current measurement of the output current.

This implementation may instead use an output shunt resistor with improved accuracy because the shunt resistor will carry only the amplifier output current, as shown in FIG. 19. However, the implementation is more complex, requiring higher voltage difference amplifiers for the current measurement as well as level-shifters to reference the voltage to the supply rails.

For the sake of brevity, conventional techniques related to making and using aspects of the disclosure may or may not be described in detail herein. In particular, various aspects of fabricating and packaging circuits, integrated circuits, and associated systems are well known. Moreover, the various tasks and process steps described herein can be incorporated into a more comprehensive procedure or process having additional steps or functionality not described in detail herein. Accordingly, many conventional steps and/or implementations are only mentioned briefly herein or are omitted entirely without providing the well-known process or implementation details.

In the context of the various systems, methods, and operations depicted and/or described herein, the terms “circuit,” “circuits,” “circuitry,” and variations thereof are used herein to refer to hardware that implements electrical or electronic functions, including without limitation discrete components, integrated circuits, application specific integrated circuits, field programmable gate arrays, mixed signal devices, and combinations thereof. Unless the context clearly indicates otherwise, these terms encompass analog, digital, and mixed signal implementations, as well as combinations of fixed function logic and programmable logic. These terms also encompass the interconnections and supporting elements that enable operation of the foregoing hardware, such as resistors, capacitors, inductors, transistors, amplifiers, logic gates, memory elements, oscillators, bias networks, interconnects, and power and ground connections. The terms do not require any particular level of integration or packaging and can refer to a single component, a portion of a component, or a combination of components that together perform one or more stated functions.

In the context of the various systems and circuits depicted and/or described herein, the terms “stage,” “stages,” and variations thereof are used herein to refer to identifiable portions of a signal path or control path that accept an input, perform an operation, and produce an output. A stage can include one or more subcircuits or blocks arranged to achieve amplification, conversion, filtering, comparison, buffering, generation, or other processing. Stages can be analog, digital, or mixed signal and can operate sequentially, concurrently, or conditionally based on control signals. The use of stage terminology does not require any particular level of integration or physical separation, and a single stage can be implemented by multiple circuits, while multiple stages can be implemented within a single circuit.

The systems and methods disclosed herein can be embodied in various forms including, for example, a data processor, such as a computer that also includes a database, digital electronic circuitry, firmware, software, or in combinations of them. Moreover, the above-noted features and other aspects and principles of the present disclosed implementations can be implemented in various environments. Such environments and related applications can be specially constructed for performing the various processes and operations according to the disclosed implementations or they can include a general-purpose computer or computing platform selectively activated or reconfigured by code to provide the necessary functionality. The processes disclosed herein are not inherently related to any particular computer, network, architecture, environment, or other apparatus, and can be implemented by a suitable combination of hardware, software, and/or firmware. For example, various general-purpose machines can be used with programs written in accordance with teachings of the disclosed implementations, or it can be more convenient to construct a specialized apparatus or system to perform the required methods and techniques.

Although ordinal numbers such as first, second and the like can, in some situations, relate to an order; as used in a document ordinal numbers do not necessarily imply an order. For example, ordinal numbers can be merely used to distinguish one item from another. For example, to distinguish a first event from a second event, but need not imply any chronological ordering or a fixed reference system (such that a first event in one paragraph of the description can be different from a first event in another paragraph of the description.

It is noted that the above-described embodiments may comprise software and/or computer programs. These computer programs, which can also be referred to programs, software, software applications, applications, components, or code, include program instructions (i.e., machine instructions) for a programmable processor, and can be implemented in a high-level procedural and/or object-oriented programming language, and/or in assembly/machine language. As used herein, the term “machine-readable storage medium” refers to any computer program product, apparatus and/or device, such as for example magnetic discs, optical disks, memory, and Programmable Logic Devices (PLDs), used to provide machine instructions and/or data to a programmable processor, including a machine-readable medium that receives program instructions as a machine-readable signal. The term “machine-readable signal” refers to any signal used to provide machine instructions and/or data to a programmable processor. The machine-readable storage medium can store such program instructions non-transitorily, such as for example would a non-transient solid-state memory or a magnetic hard drive or any equivalent storage medium. The machine-readable storage medium can alternatively or additionally store such machine instructions in a transient manner, such as would a processor cache or other random-access memory associated with one or more physical processor cores.

In various embodiments, the program instructions that implement the methods and/or mechanisms may be conveyed or stored on a non-transitory computer readable storage medium. Numerous types of media which are configured to store program instructions are available and include hard disks, floppy disks, CD-ROM, DVD, flash memory, Programmable ROMs (PROM), random access memory (RAM), and various other forms of volatile or non-volatile storage.

Non-transitory computer program products (i.e., physically embodied computer program products) are also described that store instructions, which when executed by one or more data processors of one or more computing systems, causes at least one data processor to perform operations herein. Similarly, computer systems are also described that may include one or more data processors and memory coupled to the one or more data processors. The memory may temporarily or permanently store instructions that cause at least one processor to perform one or more of the operations described herein. In addition, methods can be implemented by one or more data processors either within a single computing system or distributed among two or more computing systems. Such computing systems can be connected and can exchange data and/or commands or other instructions or the like via one or more connections, including a connection over a network (e.g., the Internet, a wireless wide area network, a local area network, a wide area network, a wired network, or the like), via a direct connection between one or more of the multiple computing systems, etc.

To provide for interaction with a user, the subject matter described herein can be implemented on a computer having a display device, such as for example a cathode ray tube (CRT) or a liquid crystal display (LCD) monitor for displaying information to the user and a keyboard and a pointing device, such as for example a mouse or a trackball, by which the user can provide input to the computer. Other kinds of devices can be used to provide for interaction with a user as well. For example, feedback provided to the user can be any form of sensory feedback, such as for example visual feedback, auditory feedback, or tactile feedback; and input from the user can be received in any form, including acoustic, speech, or tactile input.

The subject matter described herein can be implemented in a computing system that includes a back-end component, such as for example one or more data servers, or that includes a middleware component, such as for example one or more application servers, or that includes a front-end component, such as for example one or more client computers having a graphical user interface or a web browser through which a user can interact with an implementation of the subject matter described herein, or any combination of such back-end, middleware, or front-end components. The components of the system can be interconnected by any form or medium of digital data communication, such as for example a communication network. Examples of communication networks include, but are not limited to, a local area network (“LAN”), a wide area network (“WAN”), and the Internet.

A computing system may include clients and servers. A client and server are generally, but not exclusively, remote from each other and typically interact through a communication network. The relationship of client and server arises by virtue of computer programs running on the respective computers and having a client-server relationship to each other.

In various embodiments, one or more portions of the methods and mechanisms described herein may form part of a cloud-computing environment. In such embodiments, resources may be provided over the Internet as services according to one or more various models. Such models may include Infrastructure as a Service (IaaS), Platform as a Service (PaaS), and Software as a Service (SaaS). In IaaS, computer infrastructure is delivered as a service. In such a case, the computing equipment is generally owned and operated by the service provider. In the PaaS model, software tools and underlying equipment used by developers to develop software solutions may be provided as a service and hosted by the service provider. SaaS typically includes a service provider licensing software as a service on demand. The service provider may host the software, or may deploy the software to a customer for a given period of time. Numerous combinations of the above models are possible and are contemplated.

In this detailed description, numerous specific details are set forth to provide a thorough understanding of the methods and mechanisms presented herein. However, one having ordinary skill in the art should recognize that the various embodiments may be practiced without these specific details. In some instances, well-known structures, components, signals, computer program instructions, and techniques have not been shown in detail to avoid obscuring the approaches described herein. It will be appreciated that for simplicity and clarity of illustration, elements shown in the figures have not necessarily been drawn to scale. For example, the dimensions of some of the elements may be exaggerated relative to other elements.

This specification includes references to “one embodiment”. The appearance of the phrase “in one embodiment” in different contexts does not necessarily refer to the same embodiment. Particular features, structures, or characteristics may be combined in any suitable manner consistent with this disclosure. Furthermore, as used throughout this application, the word “may” is used in a permissive sense (i.e., meaning having the potential to), rather than the mandatory sense (i.e., meaning must). Similarly, the words “include”, “including”, and “includes” mean including, but not limited to.

Terminology. The following paragraphs provide definitions and/or context for terms found in this disclosure (including the appended claims):

“Comprising.” This term is open-ended. As used in the appended claims, this term does not foreclose additional structure or steps. Consider a claim that recites: “A system comprising an amplifier . . . ” Such a claim does not foreclose the system from including additional components (e.g., a capacitor, a resistor, a central processing unit).

“Configured To.” Various units, circuits, or other components may be described or claimed as “configured to” perform a task or tasks. In such contexts, “configured to” is used to connote structure by indicating that the units/circuits/components include structure (e.g., circuitry) that performs the task or tasks during operation. As such, the unit/circuit/component can be said to be configured to perform the task even when the specified unit/circuit/component is not currently operational (e.g., is not on). The units/circuits/components used with the “configured to” language include hardware—for example, circuits, memory storing program instructions executable to implement the operation, etc. Reciting that a unit/circuit/component is “configured to” perform one or more tasks is expressly intended not to invoke 35 U.S.C. § 112, paragraph (f), for that unit/circuit/component. Additionally, “configured to” can include generic structure (e.g., generic circuitry) that is manipulated by software and/or firmware (e.g., an FPGA or a general-purpose processor executing software) to operate in a manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks.

In some cases, various units/circuits/components may be described herein as performing a set of task or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

The terms “about,” “substantially,” “approximately,” and variations thereof, are intended to include the degree of error associated with measurement of the particular quantity based upon the equipment available at the time of filing the application. For example, “about,” “substantially,” “approximately,” and variations thereof can include a range of ±8% or 5%, or 2% of a given value.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

In the descriptions above and in the claims, phrases such as “at least one of” or “one or more of” may occur followed by a conjunctive list of elements or features. The term “and/or” may also occur in a list of two or more elements or features. Unless otherwise implicitly or explicitly contradicted by the context in which it used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C;” “one or more of A, B, and C;” and “A, B, and/or C” are each intended to mean “A alone, B alone, C alone, A and B together, A and C together, B and C together, or A and B and C together.” Use of the term “based on,” above and in the claims is intended to mean, “based at least in part on,” such that an unrecited feature or element is also permissible.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” or is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, circuit, a system having a processor unit and a memory storing program instructions executable to implement the task, etc. This phrase is not used herein to refer to something intangible.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “clamping unit” may be described as performing the function of “clamp an output of an amplifier,” which means that the clamping unit is “configured to” perform this function. This specification of function is sufficient, to those skilled in the computer arts, to connote a set of possible structures for the circuit.

In various embodiments, as discussed in the preceding paragraph, circuits, units, and other elements defined by the functions or operations that they are configured to implement, The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and other circuit elements (e.g. passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. An apparatus comprising
a clamping circuit configured to electronically couple to an amplifier circuit;
the clamping circuit comprising a measurement stage and an output stage;
wherein the measurement stage is configured to, responsive to a determination that an output current of the amplifier circuit is below a threshold, control the output stage to maintain a first impedance influence at one or more internal control nodes of the amplifier circuit;
wherein the first impedance influence does not substantially alter a performance shaping operation applied to an output drive of the amplifier circuit;
wherein the measurement stage is further configured to, responsive to a determination that the output current of the amplifier circuit is above a threshold, control the output stage to apply a second impedance influence at the one or more internal control nodes of the amplifier circuit; and
wherein the second impedance influence applies a current clamping function at the output drive of the amplifier circuit without shutting the amplifier circuit down.

2. The apparatus of claim 1, wherein the clamping circuit is external to the amplifier circuit and further configured to couple to the one or more internal control nodes through one or more internal control node interfaces.

3. The apparatus of claim 2, wherein:
the one or more internal control nodes comprise a first internal control node and a second internal control node; and
the one or more internal control node interfaces comprise a first internal control node interface and a second internal control node interface.

4. The apparatus of claim 3, wherein the clamping circuit is further configured to independently drive the first and second internal control node interfaces to limit sourcing current and sinking current with independently set thresholds.

5. The apparatus of claim 4, wherein:
the first internal control node interface comprises a first complementary compensation pin of the amplifier circuit; and
the second internal control node interface comprises a second complementary compensation pin of the amplifier circuit.

6. The apparatus of claim 5, wherein the performance shaping operation comprises controlling, through the one or more internal control nodes, an output frequency response of the output stage.

7. An apparatus comprising:
an amplifier comprising at least one external compensation pin; and
a clamping circuit configured to clamp an output current generated by the amplifier, wherein the clamping circuit is coupled to the at least one external compensation pin.

8. The apparatus of claim 7, wherein the clamping circuit is coupled between an output port of the amplifier and the at least one external compensation pin.

9. The apparatus of claim 7, wherein the clamping circuit is coupled between a supply voltage of the amplifier and the at least one external compensation pin.

10. The apparatus of claim 7, wherein the clamping circuit comprises one or more circuit elements.

11. The apparatus of claim 7, wherein one or more measurements of the output current generated by the amplifier are provided as inputs to the clamping circuit.

12. The apparatus of claim 11, wherein if a measured output current is less than or equal to a threshold, an output of the clamping circuit is high impedance, wherein the measured output current corresponds to the one or more measurements of the output current.

13. The apparatus of claim 12, wherein if the measured output current is greater than the threshold, the output of the clamping circuit is low impedance to a voltage value which impedes an ability of the amplifier to deliver output current.

14. A method comprising:
measuring an output current of an amplifier to generate a measured output current;
providing the measured output current as an input to a clamping circuit; and
providing an output of the clamping circuit to a first external compensation pin of the amplifier to clamp the output current generated by the amplifier.

15. The method of claim 14, wherein the first external compensation pin is connected to a gate of an output transistor of the amplifier.

16. The method of claim 14, further comprising:
measuring sourcing output current and sinking output current of the amplifier; and
driving, by the clamping circuit, the first external compensation pin and a second external compensation pin of the amplifier to achieve complementary current clamping of the output current generated by the amplifier.

17. The method of claim 16, wherein the first external compensation pin is connected to a gate of a p-type output transistor of the amplifier, and wherein the second external compensation pin is connected to a gate of an n-type output transistor of the amplifier.

18. The method of claim 17, wherein if a measured sourcing output current is above a threshold, an output of the clamping circuit is low impedance at the first external compensation pin to a positive supply voltage.

19. The method of claim 18, wherein if a measured sinking output current is above the threshold, an output of the clamping circuit is low impedance at the second external compensation pin to a negative supply voltage.

20. The method of claim 14, wherein the clamping circuit comprises a supply shunt resistor enabling independent control of both a source threshold and a sink threshold.
